(19) United States
(12) Patent Application Publication
(10) Pub. No.: US 2026/0372076 A1
(43) Pub. Date: Nov. 19, 2026

(54) INTEGRATED CIRCUIT PACKAGES AND METHODS OF FORMING THE SAME

(71) Applicant: Taiwan Semiconductor Manufacturing Co., Ltd., Hsinchu (TW)

(72) Inventors: Chang-Jung Hsueh, Taipei (TW); Po-Yao Lin, Zhudong Township (TW); Hui-Min Huang, Taoyuan City (TW); Ming-Da Cheng, Taoyuan City (TW); Kathy Yan, Hsinchu (TW)

(21) Appl. No.: 19/749,985

(22) Filed: Jul. 22, 2026

Related U.S. Application Data
(62) Division of application No. 18/151,222, filed on Jan. 6, 2023.
(60) Provisional application No. 63/416,246, filed on Oct. 14, 2022.

(51) Int. Cl. H10W 40/22; H10B 80/00; H10W 40/00; H10W 40/70; H10W 70/60; H10W 76/12; H10W 76/15; H10W 90/00; H10W 72/00; H10W 74/01; H10W 74/15; H10W 76/10; H10W 76/60; H10W 76/63

(52) U.S. Cl. CPC H10W 40/22; H10B 80/00; H10W 40/037; H10W 40/70; H10W 70/611; H10W 76/12; H10W 76/15; H10W 90/401; H10W 72/851; H10W 74/012; H10W 74/15; H10W 76/10; H10W 76/60; H10W 76/63; H10W 90/701; H10W 90/724; H10W 90/734; H10W 90/736

(57) ABSTRACT

A method includes attaching a package component to a package substrate, the package component includes: an interposer disposed over the package substrate; a first die disposed along the interposer; and a second die disposed along the interposer, the second die being laterally adjacent the first die; attaching a first thermal interface material to the first die, the first thermal interface material being composed of a first material; attaching a second thermal interface material to the second die, the second thermal interface material being composed of a second material different from the first material; and attaching a lid assembly to the package substrate, the lid assembly being further attached to the first thermal interface material and the second thermal interface material.

### PRIORITY CLAIM AND CROSS-REFERENCE

This application is a divisional of U.S. Patent Application No. 18/151,222, filed Jan. 6, 2023, which claims the benefit of U.S. Provisional Application No. 63/416,246, filed on Oct. 14, 2022, which applications are hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a tendency for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an integrated circuit die.

FIGS. 2-9C are views of intermediate stages in the manufacturing of integrated circuit packages, in accordance with some embodiments.

FIGS. 10A-10D are views of intermediate stages in the manufacturing of integrated circuit packages, in accordance with some embodiments.

FIGS. 11A-11B are views of intermediate stages in the manufacturing of integrated circuit packages, in accordance with some embodiments.

FIGS. 12A-12B are views of intermediate stages in the manufacturing of integrated circuit packages, in accordance with some embodiments.

FIG. 13 is a cross-sectional view of intermediate stages in the manufacturing of integrated circuit packages, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, integrated circuit packages are formed by packaging integrated circuit dies over a wafer. The integrated circuit dies may include first and second integrated circuit dies, wherein the first integrated circuit dies will tend to generate higher amounts of heat than the second integrated circuit dies during functional use. Encapsulant is formed over the wafer and around the integrated circuit dies. The wafer is singulated to form intermediate package components, which are then attached to package substrates to form partial semiconductor packages. A heat sink structure, including thermal interface materials (TIMs) and a lid assembly, is attached to the partial semiconductor packages to form the integrated circuit packages. In some embodiments, the heat sink structure is formed by attaching a first TIM (e.g., a metallic material) to the first integrated circuit dies and a second TIM (e.g., a low stress, non-metallic, and/or less thermally conductive material) to the second integrated circuit dies. The lid assembly is attached to the package substrate and to the TIMs. In some embodiments, the lid assembly may have an inner surface that is conformal to the TIMs, which may have non-level surfaces. The lid assembly may include other features in its shape, such as cavities and trenches designed to improve performance. The heat sink structure (e.g., the TIMs and the lid assembly) advantageously dissipates heat from the integrated circuit dies with improved efficiency, while improving the structural integrity of the integrated circuit package with greater flexibility and improved stress reduction.

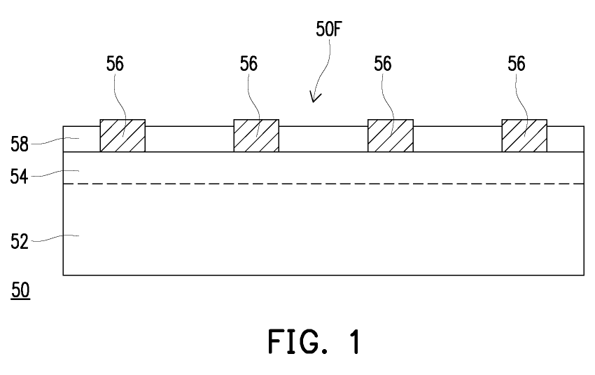

FIG. 1 is a cross-sectional view of an integrated circuit die 50. Integrated circuit dies 50 will be packaged in subsequent processing to form integrated circuit packages. Each integrated circuit die 50 may be a logic device (e.g., central processing unit (CPU), graphics processing unit (GPU), microcontroller, etc.), a memory device (e.g., dynamic random access memory (DRAM) die, static random access memory (SRAM) die, etc.), a power management device (e.g., power management integrated circuit (PMIC) die), a radio frequency (RF) device, a sensor device, a micro-electro-mechanical-system (MEMS) device, a signal processing device (e.g., digital signal processing (DSP) die), a front-end device (e.g., analog front-end (AFE) dies), the like, or a combination thereof (e.g., a system-on-a-chip (SoC) die). The integrated circuit die 50 may be formed in a wafer, which may include different die regions that are singulated in subsequent steps to form a plurality of integrated circuit dies 50. The integrated circuit die 50 includes a semiconductor substrate 52, an interconnect structure 54, die connectors 56, and a dielectric layer 58.

The semiconductor substrate 52 may be a substrate of silicon, doped or undoped, or an active layer of a semiconductor-on-insulator (SOI) substrate. The semiconductor substrate 52 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The semiconductor substrate 52 has an active surface (e.g., the surface facing upward) and an inactive surface (e.g., the surface facing downward). Devices are at the active surface of the semiconductor substrate 52. The devices may be active devices (e.g., transistors, diodes, etc.), capacitors, resistors, etc. The inactive surface may be free from devices.

The interconnect structure 54 is over the active surface of the semiconductor substrate 52, and is used to electrically connect the devices of the semiconductor substrate 52 to form an integrated circuit. The interconnect structure 54 may include one or more dielectric layer(s) and respective metallization layer(s) in the dielectric layer(s). Acceptable dielectric materials for the dielectric layers include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Other dielectric materials may also be used, such as a polymer such as polybenzoxazole (PBO), polyimide, a benzocyclobuten (BCB) based polymer, or the like. The metallization layers may include conductive vias and/or conductive lines to interconnect the devices of the semiconductor substrate 52. The metallization layers may be formed of a conductive material, such as a metal, such as copper, cobalt, aluminum, gold, combinations thereof, or the like. The interconnect structure 54 may be formed by a damascene process, such as a single damascene process, a dual damascene process, or the like.

Die connectors 56 are at the front-side 50F of the integrated circuit die 50. The die connectors 56 may be conductive pillars, pads, or the like, to which external connections are made. The die connectors 56 are in and/or on the interconnect structure 54. For example, the die connectors 56 may be part of an upper metallization layer of the interconnect structure 54. The die connectors 56 can be formed of a metal, such as copper, aluminum, or the like, and can be formed by, for example, plating, or the like. In an embodiment the die connectors 56 may be microbumps, ball grid array (BGA) connectors, solder balls, metal pillars, controlled collapse chip connection (C4) bumps, electroless nickel-electroless palladium-immersion gold technique (ENEPIG) formed bumps, or the like. The die connectors 56 may include a conductive material such as solder, copper, aluminum, gold, nickel, silver, palladium, tin, the like, or a combination thereof. In some embodiments, the die connectors 56 are formed by initially forming a layer of solder through evaporation, electroplating, printing, solder transfer, ball placement, or the like. Once a layer of solder has been formed on the structure, a reflow may be performed in order to shape the material into the desired bump shapes.

Optionally, solder regions (not separately illustrated) may be disposed on the die connectors 56 during formation of the integrated circuit die 50. The solder regions may be used to perform chip probe testing on the integrated circuit die 50. For example, the solder regions may be solder balls, solder bumps, or the like, which are used to attach a chip probe to the die connectors 56. Chip probe testing may be performed on the integrated circuit die 50 to ascertain whether the integrated circuit die 50 is a known good die (KGD). Thus, only integrated circuit dies 50, which are KGDs, undergo subsequent processing are packaged, and dies which fail the chip probe testing are not packaged. After testing, the solder regions may be removed in subsequent processing steps.

A dielectric layer 58 is at the front-side 50F of the integrated circuit die 50. The dielectric layer 58 is in and/or on the interconnect structure 54. For example, the dielectric layer 58 may be an upper dielectric layer of the interconnect structure 54. The dielectric layer 58 laterally encapsulates the die connectors 56. The dielectric layer 58 may be an oxide, a nitride, a carbide, a polymer, the like, or a combination thereof. The dielectric layer 58 may be formed, for example, by spin coating, lamination, chemical vapor deposition (CVD), or the like. The dielectric layer 58 may be patterned to form openings, and the die connectors 56 may be formed in the openings. Portions of the die connectors 56 may be disposed over the dielectric layer 58 or protrude above the dielectric layer 58. In some embodiments, the dielectric layer 58 may bury the die connectors 56, such that the top surface of the dielectric layer 58 is above the top surfaces of the die connectors 56. The die connectors 56 are exposed through the dielectric layer 58 during formation of the integrated circuit die 50. Exposing the die connectors 56 may remove any solder regions that may be present on the die connectors 56. A removal process can be applied to the various layers to remove excess materials over the die connectors 56. The removal process may be a planarization process such as a chemical mechanical polish (CMP), an etch-back, combinations thereof, or the like. In some embodiments (not specifically illustrated), after the planarization process, top surfaces of the die connectors 56 and the dielectric layer 58 are substantially coplanar (within process variations) such that they are level with one another. The die connectors 56 and the dielectric layer 58 are exposed at the front-side 50F of the integrated circuit die 50.

In some embodiments, the integrated circuit die 50 is a stacked device that includes multiple semiconductor substrates 52. For example, the integrated circuit die 50 may be a memory device that includes multiple memory dies such as a hybrid memory cube (HMC) device, a high bandwidth memory (HBM) device, or the like. In such embodiments, the integrated circuit die 50 includes multiple semiconductor substrates 52 interconnected by through vias, such as through-substrate vias (TSVs) (e.g., through-silicon vias). Each of the semiconductor substrates 52 may (or may not) have a separate interconnect structure 54.

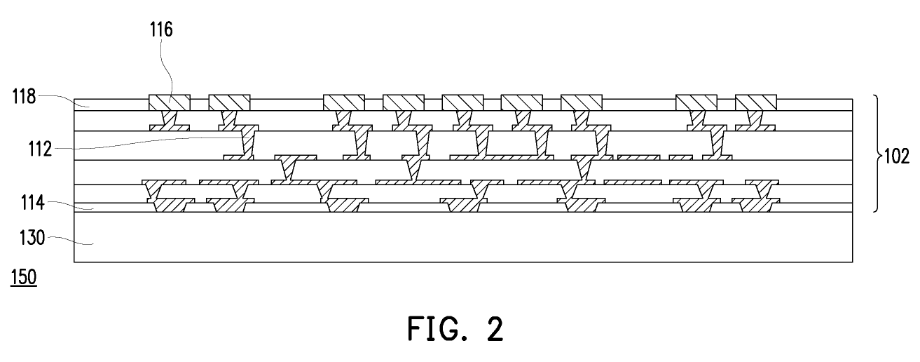

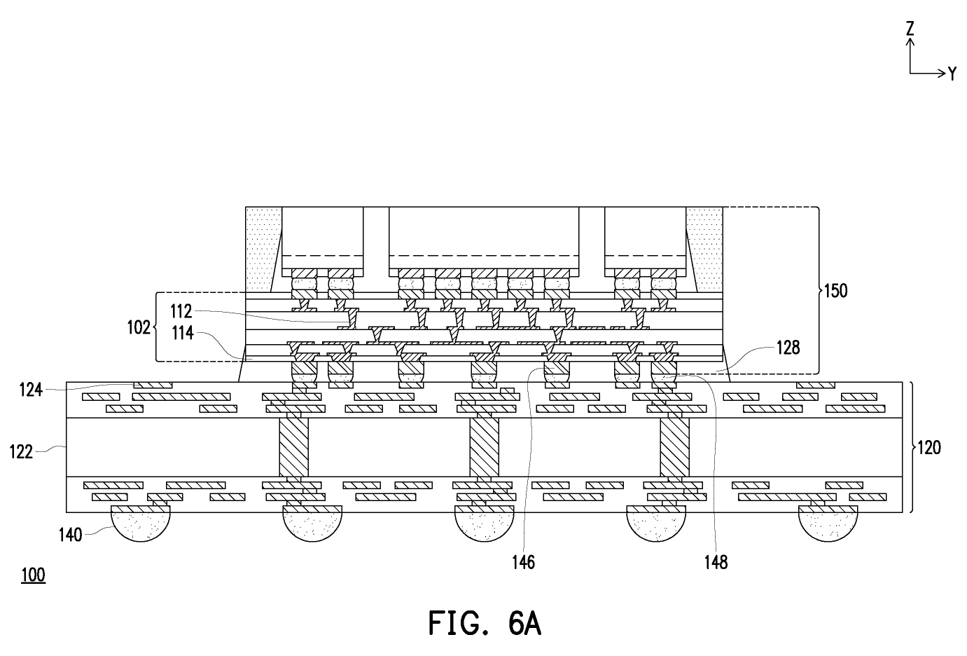

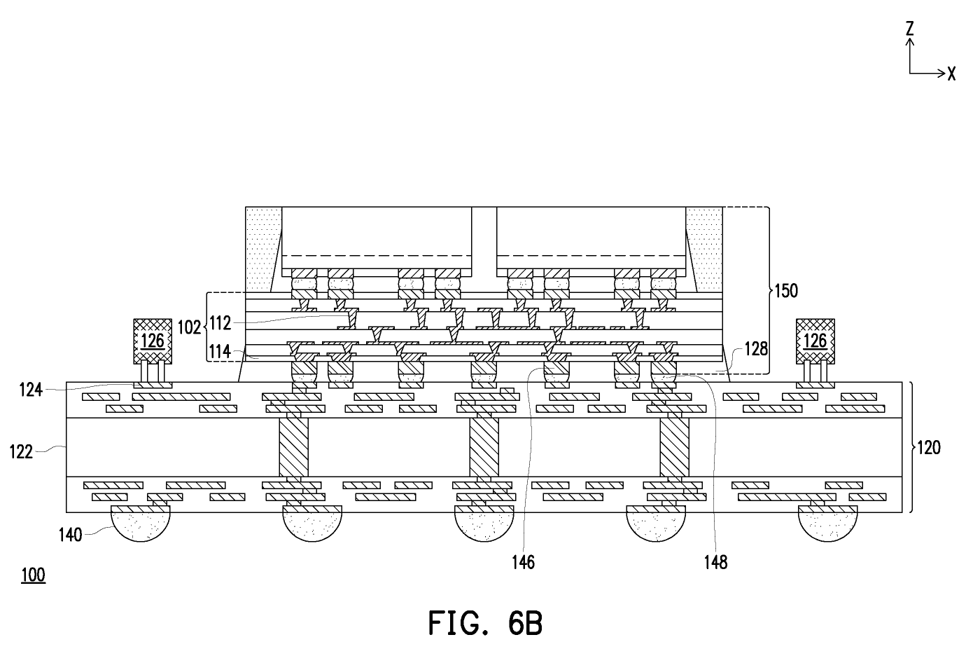

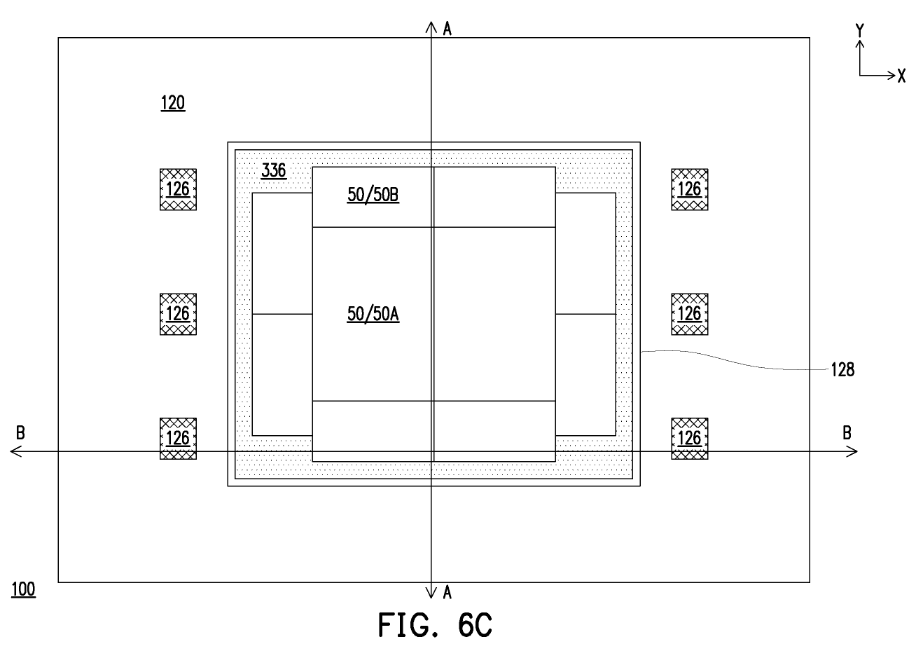

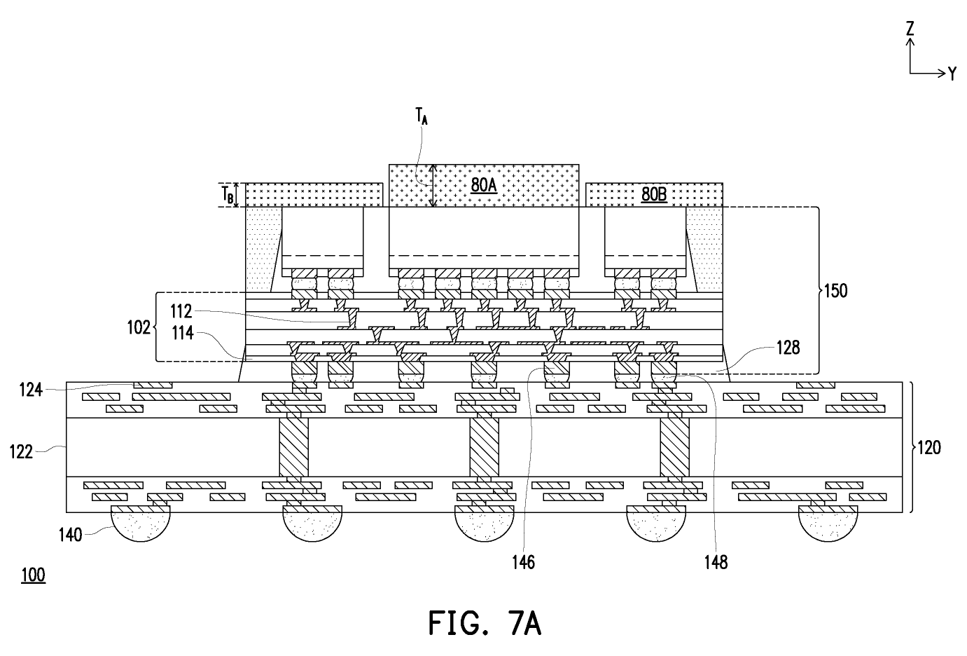

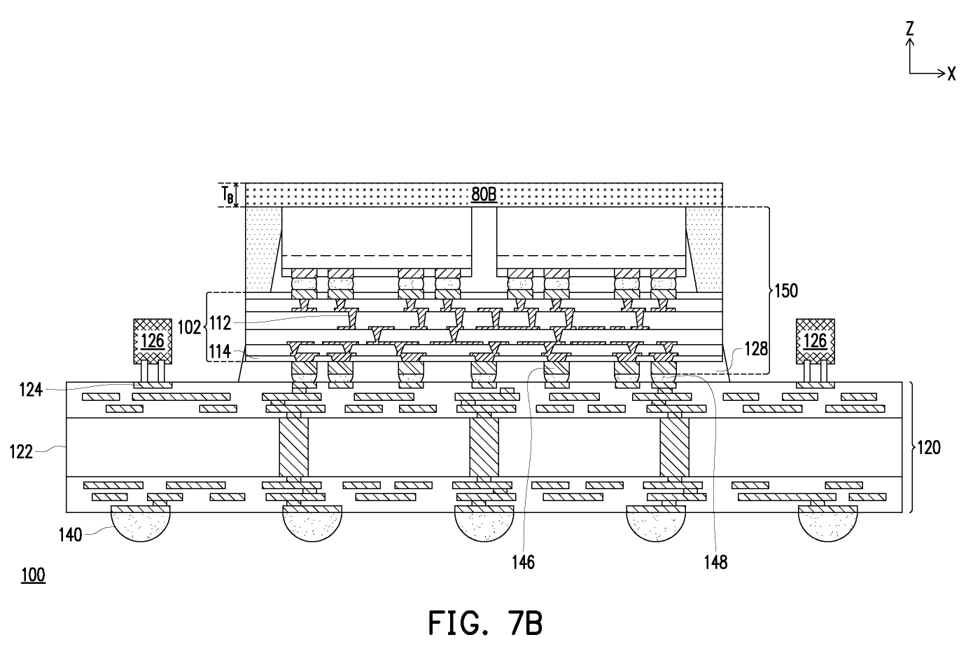

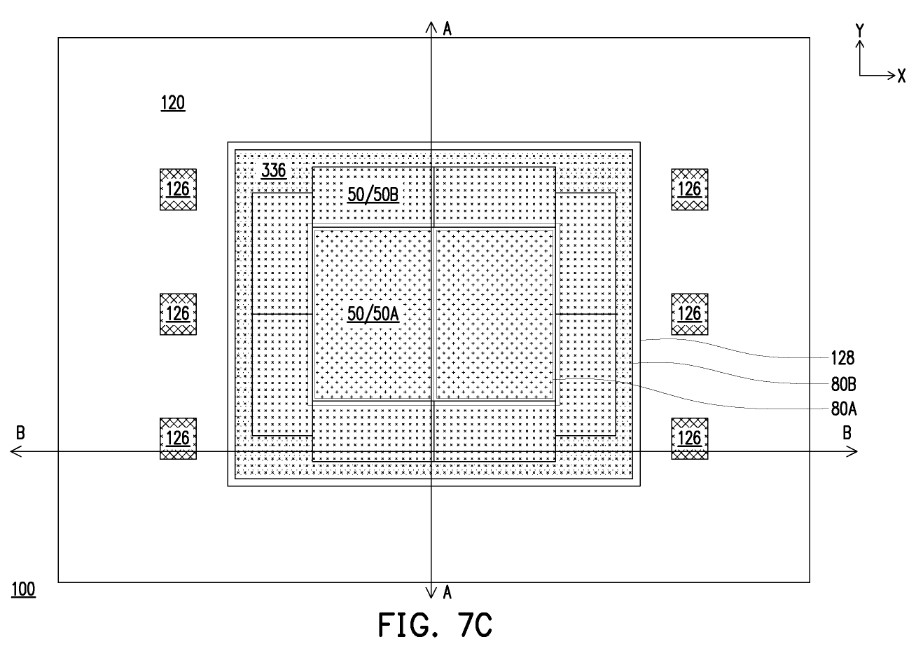

FIGS. 2-9C are views of intermediate stages in the manufacturing of integrated circuit packages 100, in accordance with some embodiments. FIGS. 2-5C are cross-sectional views of a process for forming package components 150, such as package components 150 (e.g., which include integrated circuit dies 50 attached to interposers 102). FIGS. 6A-6C are cross-sectional views of attaching the package components 150 to package substrates 120 to form the integrated circuit packages 100, such as for chip-on-wafer-on-substrate (CoWoS^{®}) devices. FIGS. 7A-9C are cross-sectional views of attaching a heat sink structure, for example, including TIMs and a lid assembly, to the package component 150 and the package substrate 120. One package region of the interposer 102 is shown for illustrative purposes, but it should be appreciated that any quantity of package regions can be simultaneously processed to form any quantity of package components 150 and subsequently singulated to form the individual package components 150.

In FIG. 2, the interposer 102 is formed over a carrier wafer 130. For example, the interposer 102 may include a plurality of metallization layers 112 embedded in a plurality of dielectric layers 114. Acceptable dielectric materials for the dielectric layers 114 include a polymer such as polybenzoxazole (PBO), polyimide, a benzocyclobuten (BCB) based polymer, or the like. Other dielectric materials may also be used, including oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. The metallization layers 112 may include conductive lines and conductive vias connecting levels of conductive lines to one another. The metallization layers 112 may be formed of a conductive material, such as a metal, such as copper, cobalt, aluminum, gold, combinations thereof, or the like.

As an example to form the interposer 102 in this embodiment, a first of the dielectric layers 114 is formed over the carrier wafer 130. In some embodiments, the carrier wafer 130 is a substrate such as a bulk semiconductor or a glass substrate. In some embodiments, the interposer 102 may be formed over an adhesive layer (not specifically illustrated) on the carrier wafer 130, which may be a laser- and/or thermal-release material which loses its adhesive property when exposed to certain wavelengths of light and/or heated. For example, the adhesive layer may be a light-to-heat-conversion (LTHC) release coating comprising an epoxy, a polyimide, an acrylic, the like, in an acetate and/or alcohol solvent, for example, or a suitable material.

Openings are formed in the first of the dielectric layers 114, and a seed layer (not separately illustrated) is formed over the first of the dielectric layers 114 and in the openings over the exposed surfaces of the carrier wafer 130. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to a first of the metallization layers 112. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, such as copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material form the first of the metallization layers 112. These steps may be repeated to form a second of the dielectric layers 114, a second of the metallization layers 112, and so on until all of the metallization layers 112 and the dielectric layers 114 of the interposer 102 are formed. In some embodiments (not specifically illustrated), the interposer 102 (e.g., the metallization layers 112 and the dielectric layers 114) may be formed by damascene processes, such as a single damascene process, a dual damascene process, the like, or combinations thereof.

In some embodiments, die connectors 116 and a dielectric layer 118 are formed over the metallization layers 112 and the dielectric layers 114. Specifically, the interposer 102 may include die connectors 116 and a dielectric layer 118 that are similar to the die connectors 56 and the dielectric layer 58 of the integrated circuit die 50 described for FIG. 1. For example, the die connectors 116 and the dielectric layer 118 may be part of an upper metallization layer 112 of the interposer 102.

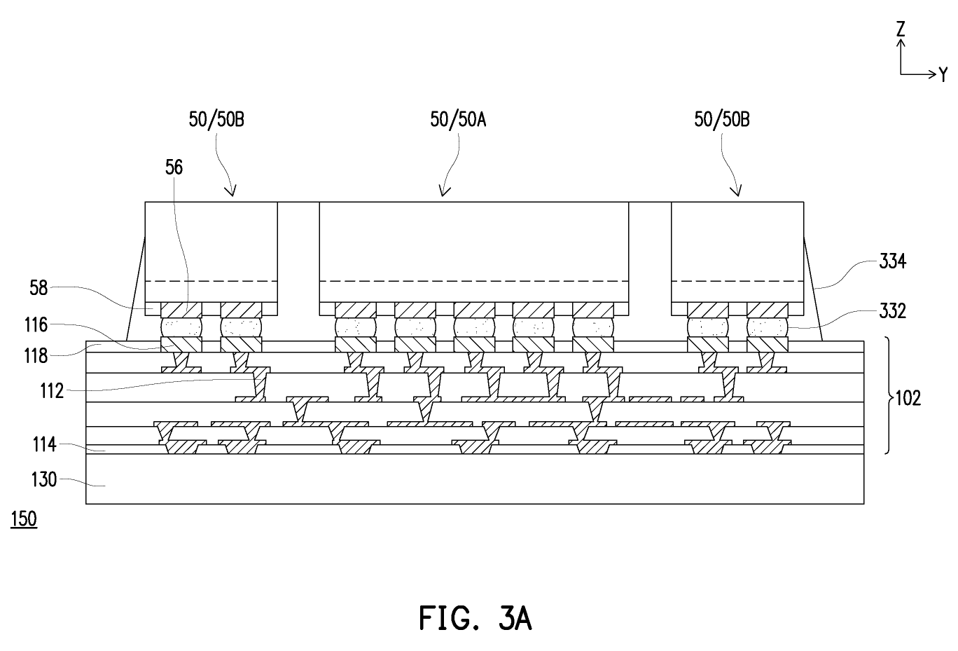

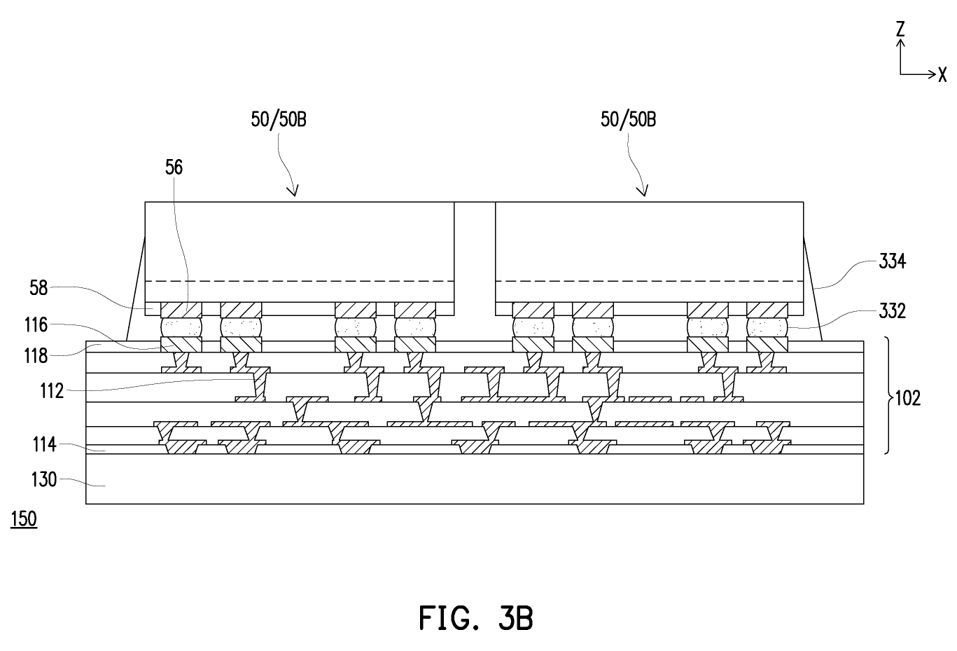

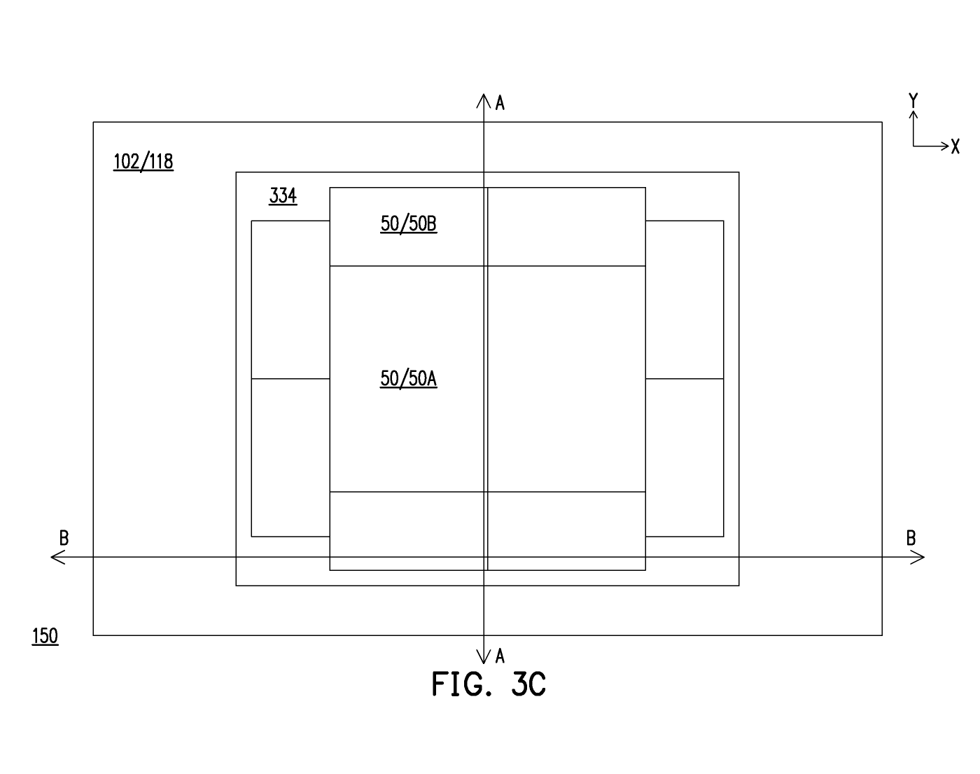

In FIGS. 3A-3C, integrated circuit dies 50 (e.g., one or more of first integrated circuit dies 50A and one or more of second integrated circuit dies 50B) are attached to the interposer 102. FIGS. 3A-3B illustrate side views of the package component 150, and FIG. 3C illustrates a plan view (e.g., X-Y plane) of the package component 150, in accordance with some embodiments. In particular, FIG. 3A illustrates the A-A cross-section (e.g., Y-Z plane) of FIG. 3C, and FIG. 3B illustrates the B-B cross-section (e.g., X-Z plane) of FIG. 3C. Note that the package component 150 of FIG. 3C is illustrated without distinguishing regions between the first integrated circuit dies 50A and the second integrated circuit dies 50B, such as the underfill 334 therebetween (if present). Subsequent plan views may be simplified in similar ways, unless otherwise stated.

In the embodiments shown, multiple integrated circuit dies 50 are placed adjacent one another, including the first integrated circuit dies 50A and the second integrated circuit dies 50B, where the first integrated circuit dies 50A are between the second integrated circuit dies 50B. In some embodiments, the first integrated circuit dies 50A are logic devices (e.g., SoC devices), such as a CPU, GPU, or the like, and the second integrated circuit dies 50B are I/O devices and/or memory devices, such as DRAM dies, HMC modules, HBM modules, or the like. Although two of the first integrated circuit dies 50A and eight of the second integrated circuit dies 50B are illustrated in various figures(e.g., the plan views), it should be appreciated that any number of each types of the integrated circuit dies 50 may be attached to the interposer 102 to form the package components 150.

In the illustrated embodiment, the integrated circuit dies 50 are attached to the interposer 102 with conductive connectors 332, such as solder bonds. The conductive connectors 332 may be formed of a conductive material that is reflowable, such as solder, copper, aluminum, gold, nickel, silver, palladium, tin, the like, or a combination thereof. In some embodiments, the conductive connectors 332 are formed by initially forming a layer of solder through methods such as evaporation, electroplating, printing, solder transfer, ball placement, or the like on the die connectors 116. Once a layer of solder has been formed on the die connectors 116, a reflow may be performed in order to shape the conductive connectors 332 into desired bump shapes. Attaching the integrated circuit dies 50 to the interposer 102 may include using, for example, a pick and place tool to place the integrated circuit dies 50 on the interposer 102 and reflowing the conductive connectors 332. The conductive connectors 332 form joints between corresponding die connectors 116 of the interposer 102 and die connectors 56 of the integrated circuit dies 50, electrically connecting the interposer 102 to the integrated circuit dies 50.

An underfill 334 may be formed around the conductive connectors 332, and between the interposer 102 and the integrated circuit dies 50. The underfill 334 may reduce stress and protect the joints resulting from the reflowing of the conductive connectors 332. The underfill 334 may be formed of an underfill material such as a molding compound, epoxy, or the like. The underfill 334 may be formed by a capillary flow process after the integrated circuit dies 50 are attached to the interposer 102, or may be formed by a suitable deposition method before the integrated circuit dies 50 are attached to the interposer 102. The underfill 334 may be applied in liquid or semi-liquid form and then subsequently cured.

In other embodiments (not specifically illustrated), the integrated circuit dies 50 are attached to the interposer 102 with direct bonds. For example, fusion bonding, dielectric bonding, metal bonding, combinations thereof (e.g., dielectric-to-dielectric bonding and metal-to-metal bonding), or the like may be used to directly bond corresponding dielectric layers 58, 118 and/or corresponding die connectors 56, 116 without the use of adhesive or solder. The underfill 334 may be omitted when direct bonding is used. Further, a mix of bonding techniques could be used, e.g., some integrated circuit dies 50 could be attached to the interposer 102 by solder bonds (e.g., the conductive connectors 332), and other integrated circuit dies 50 could be attached to the interposer 102 by direct bonds.

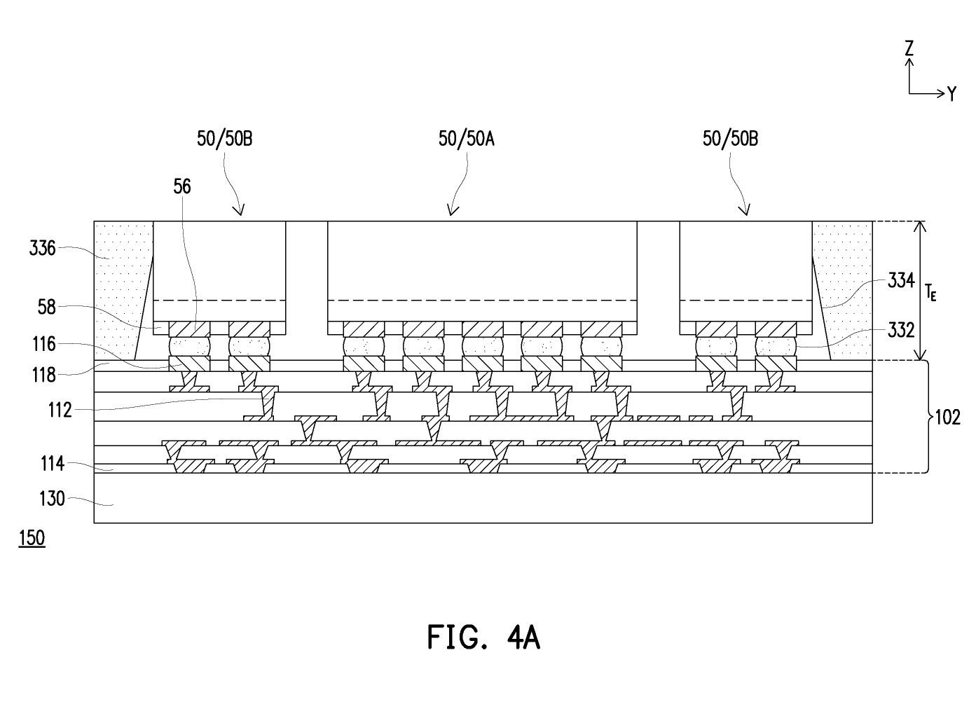

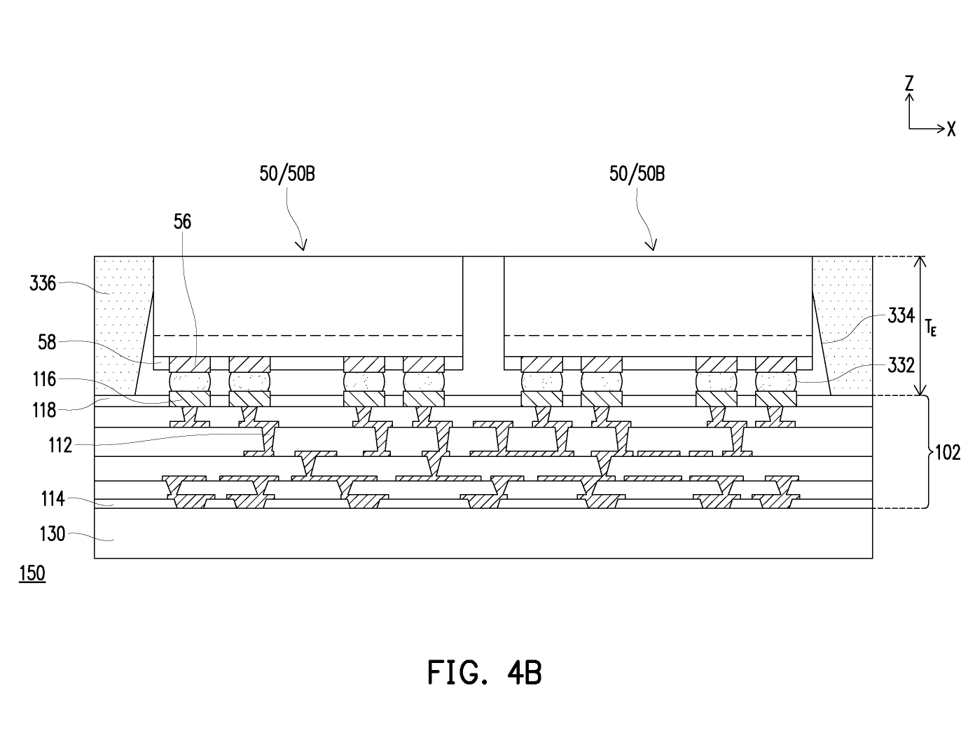

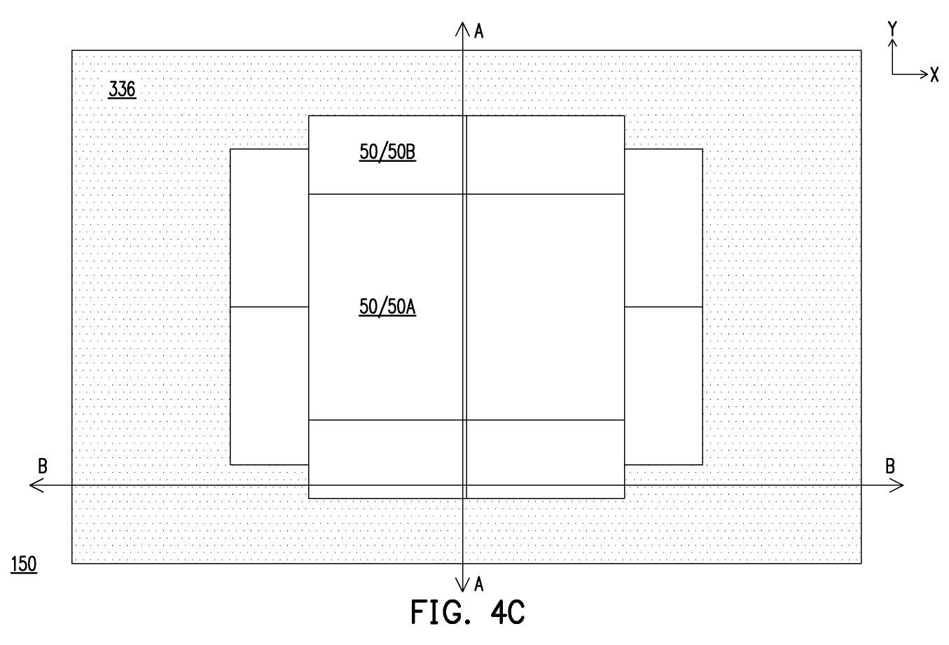

In FIGS. 4A-4C, an encapsulant 336 is formed over the interposer 102 and on and around the integrated circuit dies 50. FIGS. 4A-4B illustrate side views of the package component 150, and FIG. 4C illustrates a plan view (e.g., the X-Y plane) of the package component 150, in accordance with some embodiments. In particular, FIG. 4A illustrates the A-A cross-section (e.g., the Y-Z plane) of FIG. 4C, and FIG. 4B illustrates the B-B cross-section (e.g., the X-Z plane) of FIG. 4C.

After formation, the encapsulant 336 encapsulates the integrated circuit dies 50 as well as the underfill 334 (if present) or the conductive connectors 332. The encapsulant 336 may be a molding compound, epoxy, or the like. The encapsulant 336 may be applied by compression molding, transfer molding, or the like, and is formed over the interposer 102 such that the integrated circuit dies 50 are buried or covered. The encapsulant 336 may be applied in liquid or semi-liquid form and then subsequently cured. The encapsulant 336 may be thinned to expose the integrated circuit dies 50. The thinning process may be a grinding process, a chemical-mechanical polish (CMP), an etch-back, combinations thereof, or the like. After the thinning process, the top surfaces of the integrated circuit dies 50 and the encapsulant 336 are coplanar (within process variations) such that they are level with one another. The thinning is performed until a desired amount of the integrated circuit dies 50 and/or the encapsulant 336 has been removed. For example, the encapsulant 336 may have a thickness T_{E} above the interposer 102 ranging from 15 µm to 200 µm. Similarly, a height of the integrated circuit dies 50 above the interposer 102 may be the same as the thickness T_{E} of the encapsulant 336. In some embodiments (not specifically illustrated), the integrated circuit dies 50 may have varying thicknesses. For example, the first integrated circuit dies 50A may have greater thicknesses than the second integrated circuit dies 50B. In embodiments with two of the first integrated circuit dies 50A, the first integrated circuit dies 50A may have different thicknesses from one another.

Note that although the underfill 334 is illustrated as being formed between each of the integrated circuit dies 50 and having top surfaces that are level with the integrated circuit dies 50 and the encapsulant 336, the underfill 334 may only partially fill the gaps between the integrated circuit dies 50. As such, in some embodiments (not specifically illustrated), the encapsulant 336 is also formed at least partially between the integrated circuit dies 50, and the encapsulant 336 in those regions may be level with the integrated circuit dies 50 and the encapsulant 336 around the outermost sidewalls (e.g., perimeter) of the integrated circuit dies 50 (e.g., all of which having a height above the interposer 102 being the thickness T_{E}).

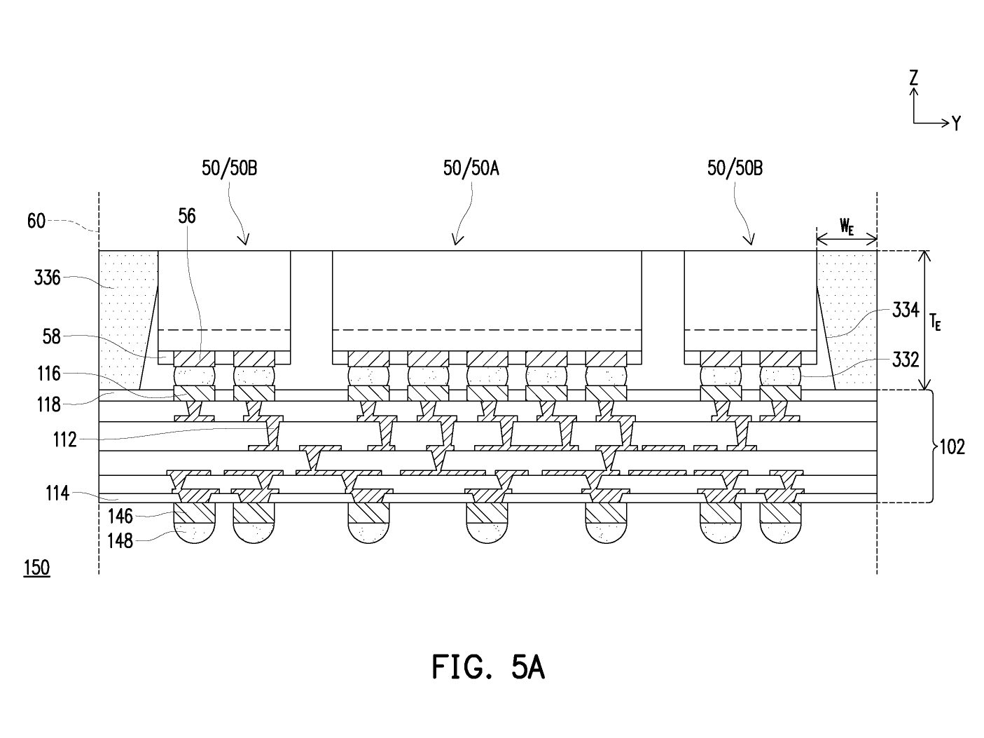

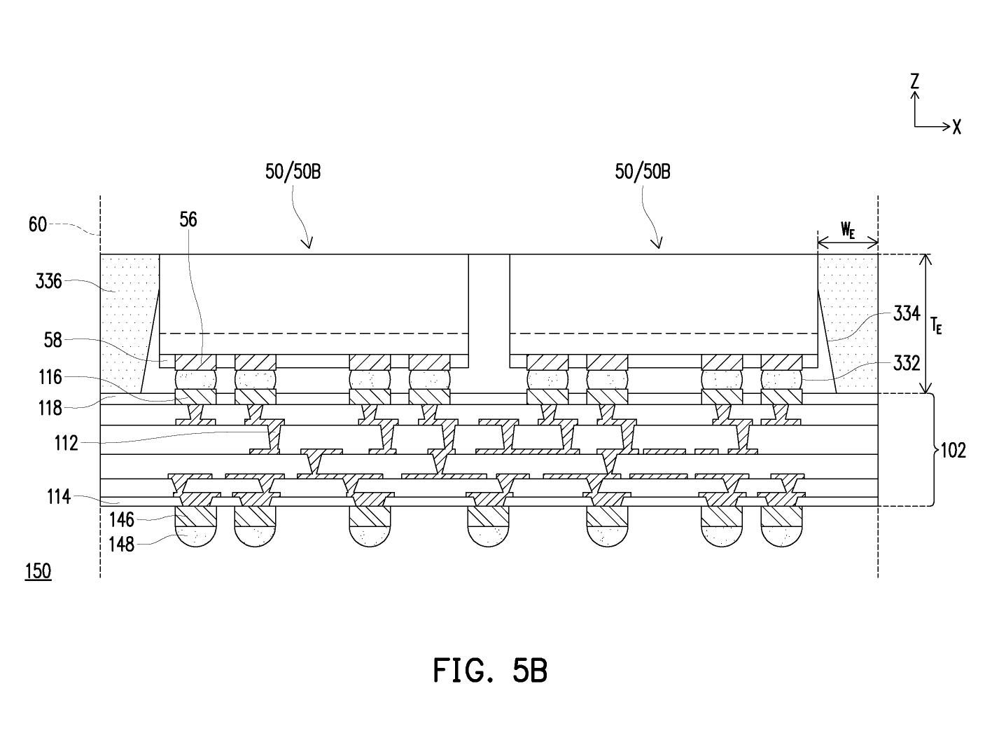

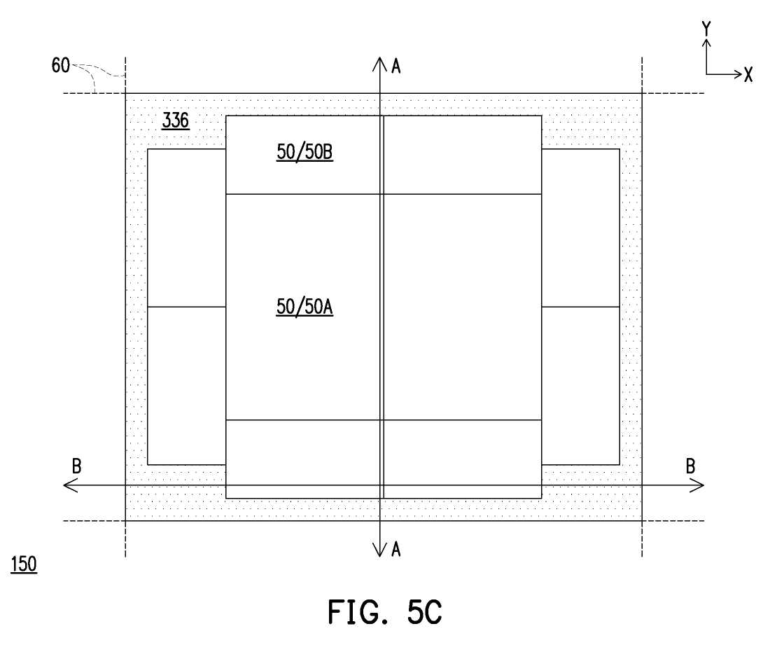

In FIGS. 5A-5C, the carrier wafer 130 is removed from the interposer 102, under-bump metallizations (UBMs) 146 are formed on the interposer 102 (e.g., the metallization layer 112), and conductive connectors 148 are formed on the UBMs 146. FIGS. 5A-5B illustrate side views of the package component 150, and FIG. 5C illustrates a plan view (e.g., the X-Y plane) of the package component 150, in accordance with some embodiments. In particular, FIG. 5A illustrates the A-A cross-section (e.g., the Y-Z plane) of FIG. 5C, and FIG. 5B illustrates the B-B cross-section (e.g., the X-Z plane) of FIG. 5C.

For example, in embodiments in which an adhesive layer (not specifically illustrated) is used to hold the interposer 102 to the carrier wafer 130, a debonding process may be performed by, e.g., projecting a light such as a laser light or an ultraviolet (UV) light on the adhesive layer so that the adhesive layer decomposes from the energy and/or the heat of the light, and the carrier wafer 130 can be removed. Optionally, an insulating layer (not specifically illustrated) may be formed on the back surface of the interposer 102. The insulating layer may be formed of a silicon-containing insulator, such as, silicon nitride, silicon oxide, silicon oxynitride, or the like, and may be formed by a suitable deposition method such as spin coating, CVD, plasma-enhanced CVD (PECVD), high density plasma CVD (HDP-CVD), or the like. For example, the insulating layer may serve as a passivation layer to protect otherwise exposed features of the metallization layer 112. If the insulating layer is present, before forming the UBMs 146 and the conductive connectors 148, the insulating layer may be patterned to form openings to expose the first of the metallization layers 112.

As an example to form the UBMs 146 in this embodiment, a seed layer (not separately illustrated) is formed over the exposed surfaces of the interposer 102. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the UBMs 146. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, such as copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material form the UBMs 146.

Further, conductive connectors 148 are formed on the UBMs 146. The conductive connectors 148 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 148 may include a conductive material such as solder, copper, aluminum, gold, nickel, silver, palladium, tin, the like, or a combination thereof. In some embodiments, the conductive connectors 148 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 148 comprise metal pillars (such as copper pillars) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

In accordance with some embodiments, the structure is singulated along scribe regions 60 to separate the package component 150 from other package components 150. The singulation process may include sawing, dicing, or the like. For example, the singulation process can include sawing the encapsulant 336, the interposer 102 (e.g., the dielectric layers 114), and the dielectric layer 118. As a result of the singulation process, the outer sidewalls of the interposer 102 and the encapsulant 336 are laterally coterminous (within process variations). After singulation, the encapsulant 336 may have a lateral thickness or width W_{E} from outer sidewalls of the integrated circuit dies 50 ranging from 250 µm to 950 µm.

FIGS. 6A-8C illustrate various additional steps in the manufacturing of the integrated circuit package 100, in accordance with various embodiments. For example, the package component 150 is attached to a package substrate 120, and other features, such as thermal interface materials (TIMs) 80 and a lid assembly 226, may be attached to the package component 150 and the package substrate 120, thus forming the integrated circuit package 100. A single package component 150, a single package substrate 120, and a single integrated circuit package 100 are illustrated. It should be appreciated that multiple package components 150 can be simultaneously processed to form multiple integrated circuit packages 100. As discussed above, the TIMs 80 and the lid assembly 226 may be collectively referred to as a heat sink structure.

In FIGS. 6A-6C, the package component 150 is attached to a package substrate 120 using the conductive connectors 148. FIGS. 6A-6B illustrate side views of the integrated circuit package 100, and FIG. 6C illustrates a plan view (e.g., the X-Y plane) of the integrated circuit package 100, in accordance with some embodiments. In particular, FIG. 6A illustrates the A-A cross-section (e.g., the Y-Z plane) of FIG. 6C, and FIG. 6B illustrates the B-B cross-section (e.g., the X-Z plane) of FIG. 6C.

In accordance with some embodiments, the package substrate 120 includes a substrate core 122, which may be made of a semiconductor material such as silicon, germanium, diamond, or the like. In some embodiments, compound materials such as silicon germanium, silicon carbide, gallium arsenic, indium arsenide, indium phosphide, silicon germanium carbide, gallium arsenic phosphide, gallium indium phosphide, combinations thereof, or the like, may also be used. Additionally, the substrate core 122 may be a SOI substrate. Generally, an SOI substrate includes a layer of a semiconductor material such as epitaxial silicon, germanium, silicon germanium, SOI, SGOI, or combinations thereof. In another embodiment, the substrate core 122 is an insulating core such as a fiberglass reinforced resin core. One example core material is fiberglass resin such as FR4. Alternatives for the core material include bismaleimide-triazine (BT) resin, or alternatively, other printed circuit board (PCB) materials or films. Build up films such as Ajinomoto build-up film (ABF) or other laminates may be used for the substrate core 122.

The substrate core 122 may include active and passive devices (not separately illustrated). Devices such as transistors, capacitors, resistors, combinations thereof, and the like may be used to generate the structural and functional requirements of the design for the system. The devices may be formed using any suitable methods.

The substrate core 122 may also include metallization layers and vias, and bond pads 124 over the metallization layers and vias. The metallization layers may be formed over the active and passive devices and are designed to connect the various devices to form functional circuitry. The metallization layers may be formed of alternating layers of dielectric material (e.g.¸ low-k dielectric material) and conductive material (e.g., copper) with vias interconnecting the layers of conductive material, and may be formed through any suitable process (such as deposition, damascene, or the like). In some embodiments, the substrate core 122 is substantially free of active and passive devices.

The conductive connectors 148 are reflowed to attach the UBMs 146 of the interposer 102 to the bond pads 124 of the package substrate 120. The conductive connectors 148 connect the package component 150 (e.g., the metallization layers 112 of the interposer 102) to the package substrate 120 (e.g., metallization layers of the substrate core 122). Thus, the package substrate 120 is electrically connected to the integrated circuit dies 50. In some embodiments, passive devices (e.g., surface mount devices (SMDs), not specifically illustrated) may be attached to the package component 150 (e.g., bonded to the UBMs 146) prior to mounting on the package substrate 120. In such embodiments, the passive devices may be bonded to a same surface of the package component 150 as the conductive connectors 148. In some embodiments, passive devices 126 (e.g., SMDs) may be attached to the package substrate 120, e.g., to the bond pads 124. For example, the passive devices 126 may be attached to the package substrate 120 before attaching the package component 150 to the package substrate 120.

In some embodiments, an underfill 128 is formed between the package component 150 and the package substrate 120, surrounding the conductive connectors 148. The underfill 128 may be formed by a capillary flow process after the package component 150 is attached or may be formed by any suitable deposition method before the package component 150 is attached. The underfill 128 may be a continuous material extending from the package substrate 120 to the interposer 102 (e.g., to the first of the dielectric layers 114). In some embodiments, some of the passive devices 126 may be attached to the package substrate 120 after forming the underfill 128.

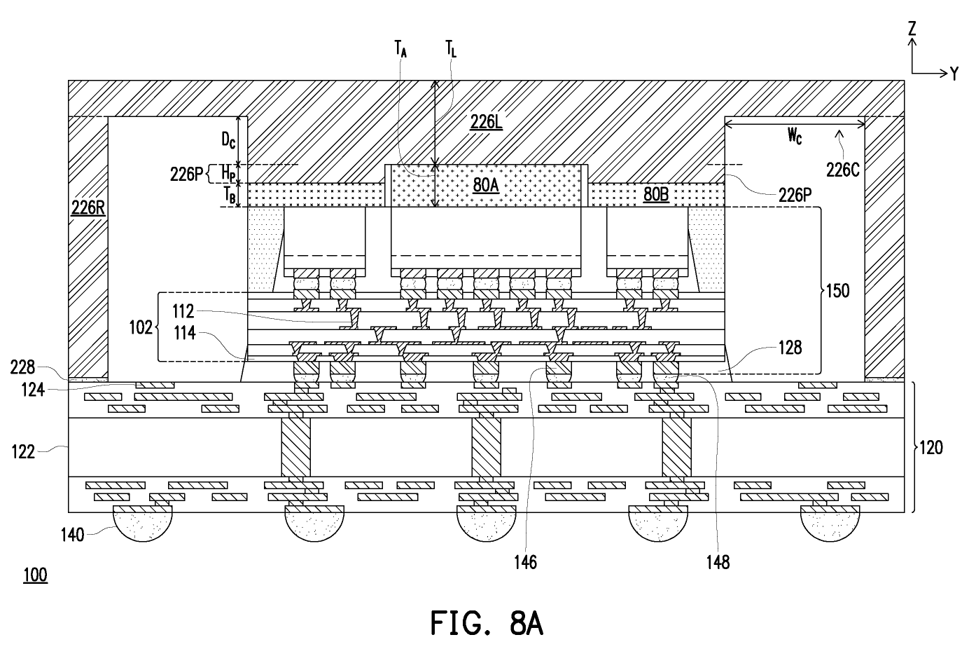

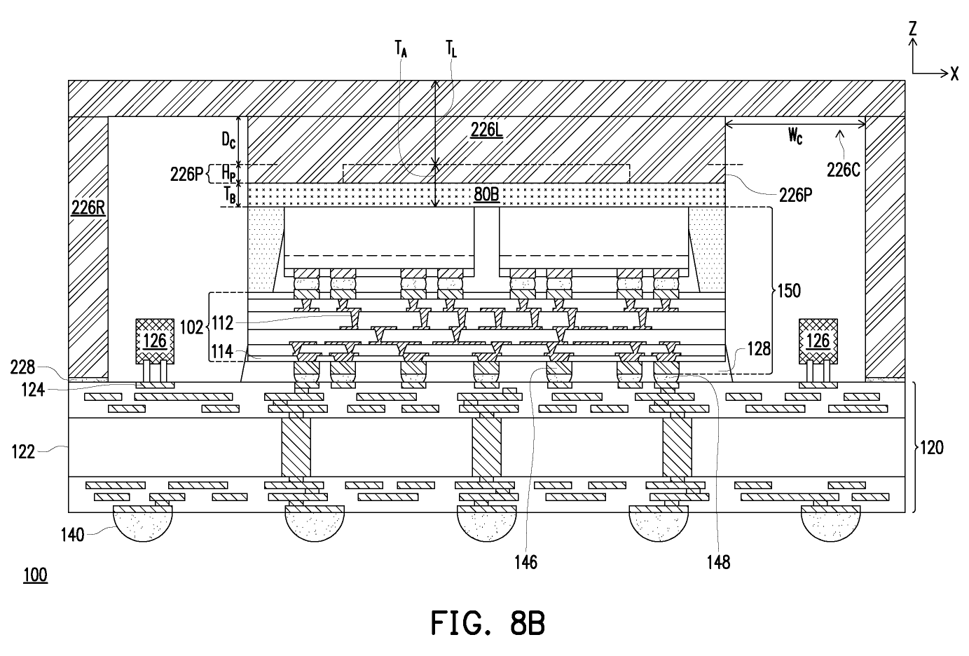

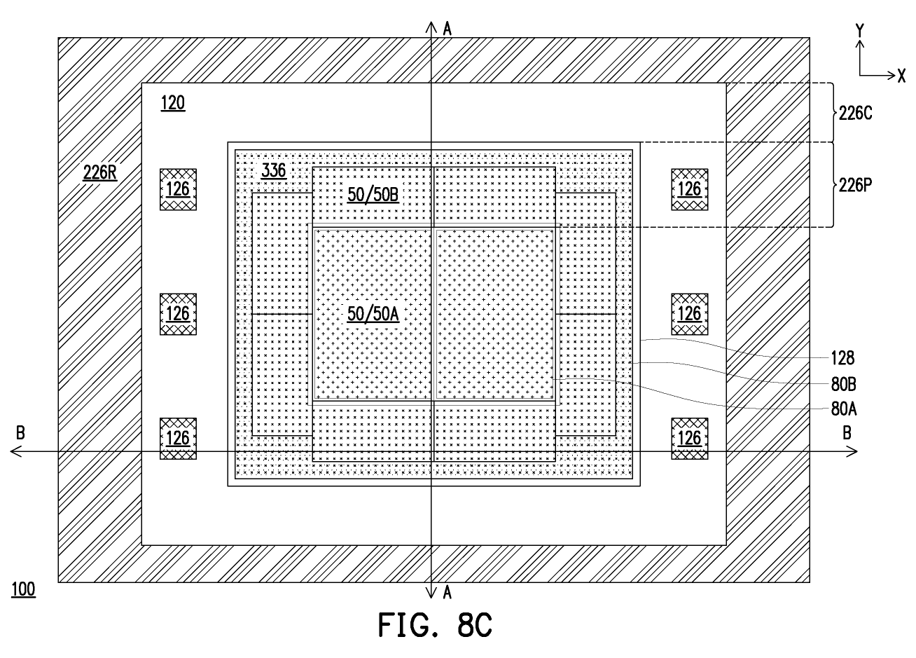

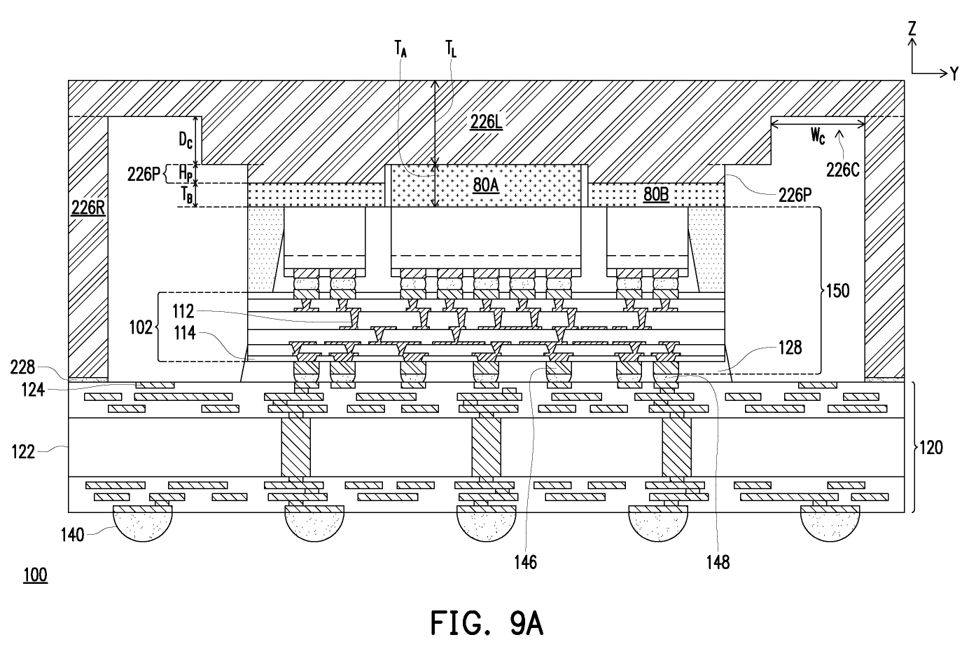

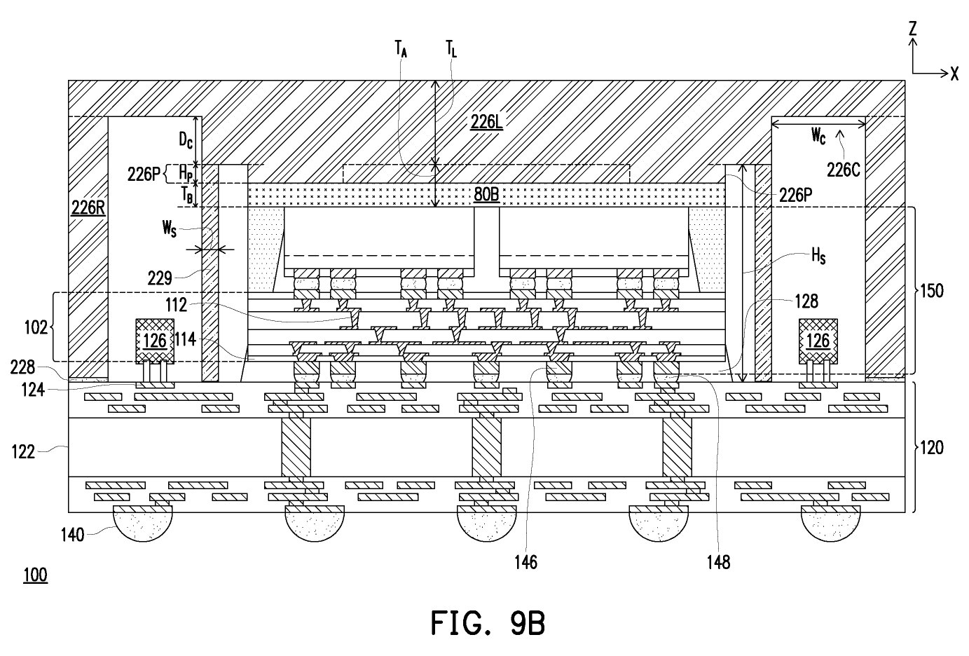

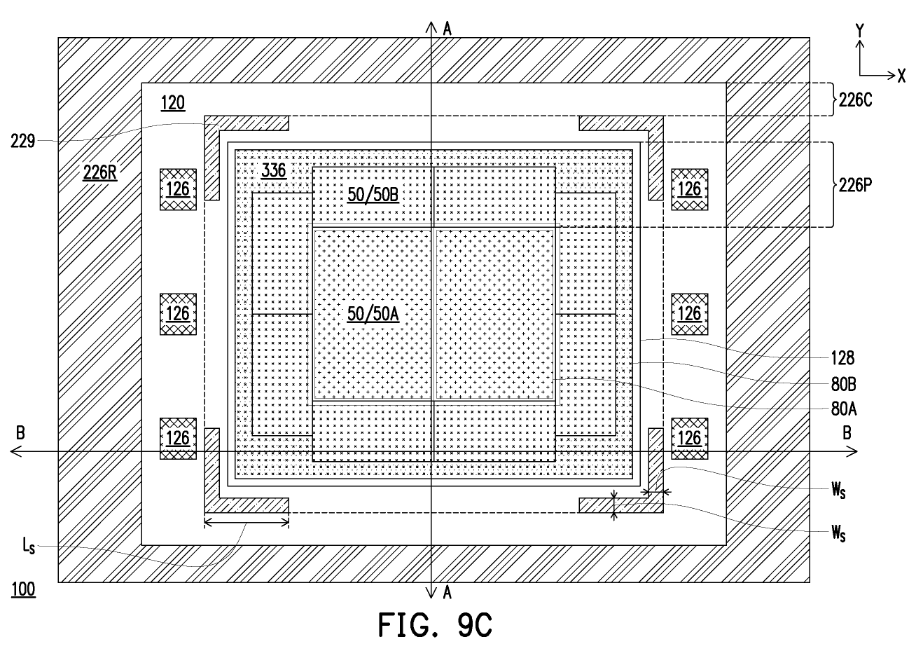

As further illustrated, the package substrate 120 may include external connectors 140 along a side opposite of attachment of the package components 150. The external connectors 140 may facilitate subsequent processing, such as testing (e.g., thermal cycle testing) and/or attachment and electrical connection of the integrated circuit package 100 in an electronic device. In some embodiments (not specifically illustrated), the external connectors 140 may be formed along the package substrate 120 during a later step, such as after attaching the lid assembly 226 (see, e.g., FIGS. 8A-9C). After attachment, the package component 150 may have a thickness above the package substrate 120 of about 1 inch.

In FIGS. 7A-7C, thermal interface materials (TIMs) 80 (e.g., also referred to as heat dissipation features) are attached to the integrated circuit dies 50. The TIMs 80 collectively form a hybrid TIM including first TIMs 80A (e.g., metallic TIMs) and second TIMs 80B (e.g., low stress TIMs). For example, the first TIMs 80A are attached to the first integrated circuit dies 50A, and the second TIMs 80B are attached to the second integrated circuit dies 50B. FIGS. 7A-7B illustrate side views of the integrated circuit package 100, and FIG. 7C illustrates a plan view (e.g., the X-Y plane) of the integrated circuit package 100, in accordance with some embodiments. In particular, FIG. 7A illustrates the A-A cross-section (e.g., the Y-Z plane) of FIG. 7C, and FIG. 7B illustrates the B-B cross-section (e.g., the X-Z plane) of FIG. 7C.

For example, the first TIM 80A includes a bulk substrate, and may be formed of a material with high thermal conductivity such as a metal, including an alloy or epoxy, comprising Ag (e.g., greater than or equal to 80 wt. %), In (e.g., 99 wt. %, or as much as 99.99 wt. %), AgIn (e.g., 90 wt. % In and 10 wt. % Ag), AgIn₂, AuIn, AuIn₂, InₓNi_{y}Au, InₓNi_{y}Ag, other materials such as silicon, ceramic, heat conductive glass, copper, iron, combinations or alloys thereof, or the like. In addition, the second TIM 80B includes a bulk substrate, and may be a low stress material (e.g., compliant, flexible, and/or soft) with high thermal conductivity such as a high-k polymer-based or graphite-based material, which may further contain conductive fillers (e.g., Al, ZnO, Ag) within. The TIMs 80 may also be referred to as heat dissipation dies, heat dissipation features, dummy dies, or thermal enhancement dies. In some embodiments, the thermal conductivity of the first TIMs 80A may be greater than the thermal conductivity of the second TIMs 80B. As such, the first TIMs 80A will effectively dissipate heat from the first integrated circuit dies 50A, which may generate more heat than the second integrated circuit dies 50B. For example, the first TIMs 80A may have a thermal conductivity ranging from 10 W/cm·K to 100 W/cm·K, and the second TIMs 80B may have a thermal conductivity ranging from 2 W/cm·K to 20 W/cm·K.

Referring to FIGS. 7A-7B, the first TIM 80A may have a thickness T_{A}, and the second TIM 80B may have a thickness T_{B}. In some embodiments, the thickness T_{A} may be greater than or equal to 1.5X the thickness T_{B}. As such, top surfaces of the TIMs 80 may be uneven. As discussed above, the first integrated circuit dies 50A may generate more heat than the second integrated circuit dies 50B, and the greater thickness T_{A} of the first TIMs 80A may improve the heat dissipation benefits.

Referring to FIG. 7C, in accordance with some embodiments, a total area (e.g., or footprint) of the first TIMs 80A may be less than or contained within a total area (e.g., or footprint) of the first integrated circuit dies 50A. In addition, a total area of the second integrated circuit dies 50B may be less than or contained within a total area of the second TIMs 80B. Further, the total area of the second TIMs 80B may be less than or equal to the total area of the first TIMs 80A. For example, a total area of the second integrated circuit dies 50B may be about 1 inch.

In accordance with some embodiments, each of the first TIMs 80A may be attached to a corresponding one of the first integrated circuit dies 50A, thereby allowing for more flexibility in choosing an appropriate material, shape, and thickness T_{A} for each of the first TIMs 80A. As such, each of the first TIMs 80A may be formed of a same or different material. For example, each material of the first TIMs 80A may be selected to provide the necessary heat dissipation for the corresponding one of the first integrated circuit dies 50A. Whether the first integrated circuit dies 50A have same or different thicknesses from one another, each of the first TIMs 80A may also have a same or different thickness T_{A}. In some embodiments, a sum of the thickness of the first integrated circuit die 50A and the thickness T_{A} of the corresponding first TIM 80A for each of the first integrated circuit dies 50A may be the same. Although not specifically illustrated, a single first TIM 80A may be disposed over multiple ones of the first integrated circuit dies 50A.

Similarly, each of the second TIMs 80B may be attached to a corresponding one of the second integrated circuit dies 50B. As illustrated, any one of the second TIMs 80B may correspond to two or more of the second integrated circuit dies 50B. In some embodiments, a single continuous second TIM 80B may be disposed over all of the integrated circuit dies 50B. For example, in embodiments in which the second integrated circuit dies 50B form a ring around the first integrated circuit dies 50A, the second TIM 80B may analogously form a ring around the first TIM 80A.

In FIGS. 8A-8C, a lid assembly 226 is attached to the package substrate 120, around the package component 150 and the passive devices 126 (if present), and over the TIMs 80. The lid assembly 226 may serve as the heat sink of the heat sink structure (e.g., collectively the lid assembly 226 and the TIMs 80). In some embodiments, the lid assembly 226 may include a ring portion 226R and a lid portion 226L. The ring portion 226R is attached to the package substrate 120 and surrounds the package component 150, and the lid portion 226L is disposed over and/or attached to the TIMs 80. FIGS. 8A-8B illustrate side views of the integrated circuit package 100, and FIG. 8C illustrates a plan view (e.g., the X-Y plane) of the integrated circuit package 100, in accordance with some embodiments. In particular, FIG. 8A illustrates the A-A cross-section (e.g., the Y-Z plane) of FIG. 8C, and FIG. 8B illustrates the B-B cross-section (e.g., the X-Z plane) of FIG. 8C.

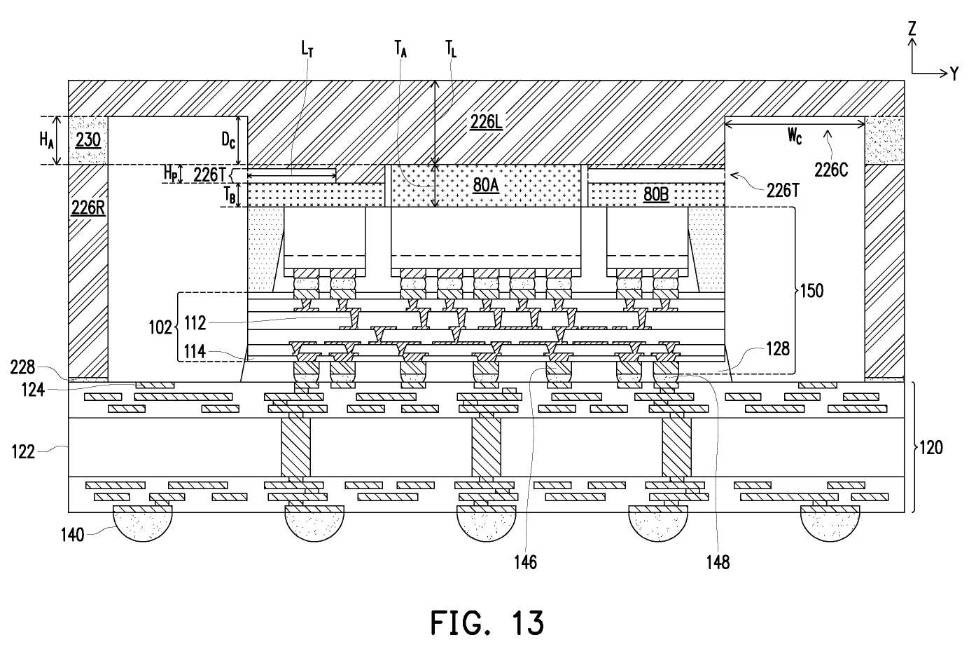

In some embodiments, the lid assembly 226 may have a rigidity greater than that of the package substrate 120, and the ring portion 226R may be configured as a stiffener ring for constraining the package substrate 120 to minimize warpage (e.g., caused by stress generated during subsequent processing steps or testing, such as thermal cycling testing) and/or to enhance the robustness of the package substrate 120. In some embodiments, the ring portion 226R is arranged along a periphery or perimeter of the package substrate 120 and surrounds the package component 150 and the passives devices 126 along the package substrate 120. In a top-down view (see FIG. 8C), the lid assembly 226 (e.g., the ring portion 226R) may have a rectangular shape depending, for example, on the size and shape of the package component 150 and the package substrate 120. In some embodiments, the ring portion 226R may be formed over the package substrate 120, and the lid portion 226L may be subsequently attached to the ring portion 226R to form the lid assembly 226 (see FIG. 13). In some embodiments (not specifically illustrated), the ring portion 226R includes one or more discontinuities, such as comprising discrete segments around the package component 150, without forming a continuous ring or loop.

The lid assembly 226 may be made of one or more materials. For example, the ring portion 226R (e.g., parts adjacent to the package substrate 120) may be formed of a rigid material having a coefficient of thermal expansion (CTE) similar to that of the underlying package substrate 120, thereby reducing CTE mismatch therebetween and reducing stress (as well as deformation) on the package substrate 120 (e.g., such as being caused by attachment of the lid assembly 226). In addition, materials of the lid portion 226L (and, optionally, parts of the ring portion 226R adjacent to the lid portion 226L) may include metals such as copper, stainless steel, stainless steel/Ni, the like, and combinations and alloys thereof. For example, the lid portion 226L may be mostly copper with a gold and/or silver coating along parts of the surface in contact with the first TIMs 80A and a nickel coating along parts of the surface in contact with the second TIMs 80B. In some embodiments, the thermal conductivity of the lid portion 226L may be greater than the thermal conductivity of the ring portion 226R. For example, the lid portion 226L may have a thermal conductivity ranging from 150 W/cm·K to 600 W/cm·K, and the ring portion 226R may have a thermal conductivity ranging from 90 W/cm·K to 600 W/cm·K.

In some embodiments, the lid assembly 226 is placed on the package substrate 120 and held in place using an adhesive layer 228 interposed between a bottom surface of the ring portion 226R of the lid assembly 226 and an upper surface of the package substrate 120. The adhesive layer 228 may be any suitable non-conductive adhesive, epoxy, die attach film (DAF), or the like, and may be applied to the bottom surface of the ring portion 226R or may be applied over the upper surface of the package substrate 120 before installing the lid assembly 226. In some embodiments, other adhesive layers (not specifically illustrated) along an inner surface of the lid portion 226L of the lid assembly 226 may be used to improve attachment of the lid assembly 226 to the first TIMs 80A and/or the second TIMs 80B.

After placing the lid assembly 226 over the package substrate 120, an optional baking process may be performed to form bonds between the TIMs 80 and the lid portion 226L. For example, the first TIMs 80A may form bonds with, e.g., the gold and/or silver coating along part of the lid portion 226L, and the second TIMs 80B may form bonds with, e.g., the nickel coating along another part of the lid portion 226L. As such, the first TIMs 80A may have strong intermetallic bonds with the lid portion 226L.

Still referring to FIGS. 8A-8C, as illustrated, the lid portion 226L may include one or more protrusions 226P extending from the lid portion 226L to the second TIMs 80B by a protrusion height H_{P}. After attaching the lid assembly 226, the protrusions 226P are adjacent to and directly over the second TIMs 80B, while a main or central part of the lid portion 226L is adjacent to and directly over the first TIMs 80A. As such, the lid assembly 226 is a conformal lid by being conformal to the top surfaces of the TIMs 80 even when those top surfaces are uneven. The conformal topography of the lid portion 226L allows for greater surface area contact with the TIMs 80, thereby improving heat dissipation from the integrated circuit dies 50.

In some embodiments, the thickness T_{A} of the first TIMs 80A is the same as a sum of the thickness T_{B} of the second TIMs 80B and the protrusion height H_{P}, thereby ensuring full contact between the lid portion 226L and all of the TIMs 80 for improved heat dissipation. In some embodiments, the thickness T_{A} may be greater than the sum of the thickness T_{B} and the protrusion height H_{P}, thereby ensuring that at least the first TIMs 80A make full contact with both the first integrated circuit dies 50A and the lid portion 226L for sufficient heat dissipation.

In accordance with some embodiments, the lid portion 226L may further include cavities 226C adjacent to the ring portion 226R of the lid assembly 226. As illustrated, a single cavity 226C may form a loop within the ring portion 226R (e.g., together forming concentric loops around the package component 150). The cavity 226C may have a cavity width W_{C}, which may be the same or different in the cross-sections of FIGS. 8A and 8B. The cavity 226C also have a cavity depth D_{C} into the lid portion 226L. The cavity 226C increases flexibility between the lid portion 226L and the ring portion 226R to ensure the lid portion 226L maintains complete contact with the TIMs 80, for example, in cases in which deformation, bending, or other warpage of the package substrate 120 causes warpage in the ring portion 226R.

In some embodiments, a ratio of the cavity height H_{C} to the thickness T_{L} of the lid portion 226L ranges from 0.1 to 0.5. Being less than or equal to 0.5 provides improved flexibility between the lid portion 226L and the ring portion 226R, and being greater than 0.1 ensures that the lid assembly 226 maintains sufficient structural integrity. In addition, the cavity width W_{C} may be greater than or equal to the protrusion height H_{P}, and, in some embodiments, also greater than a sum of the protrusion height H_{P} and the cavity depth D_{C} (e.g., a distance from the cavity 226C to a distal surface of the protrusion 226P) – thereby improving the flexibility between the lid portion 226L and the ring portion 226R.

After attachment of the lid assembly 226, the integrated circuit package 100 may undergo subsequent processing, such as testing (e.g., thermal cycle testing), and/or be attached in an electronic device. As discussed above, in some embodiments (not specifically illustrated), the external connectors 140 may be formed after attaching the lid assembly 226.

FIGS. 9A-9C illustrate an embodiment of the integrated circuit package 100 which include stiffeners 229 connecting the lid assembly 226 to the package substrate 120. In addition, the lid assembly 226 may have a narrower cavity 226C than the cavity 226C of the integrated circuit package 100 described above. The illustrated integrated circuit package 100 may be formed similarly as described above, unless otherwise specified. FIGS. 9A-9B illustrate side views of the integrated circuit package 100, and FIG. 9C illustrates a plan view (e.g., the X-Y plane) of the integrated circuit package 100, in accordance with some embodiments. In particular, FIG. 9A illustrates the A-A cross-section (e.g., the Y-Z plane) of FIG. 9C, and FIG. 9B illustrates the B-B cross-section (e.g., the X-Z plane) of FIG. 9C.

The stiffeners 229 improve the stability and rigidity of the integrated circuit package 100 when differences in coefficients of thermal expansion would otherwise cause warpages. The stiffeners 229 may be made of a same or similar material as the adhesive 228 and similarly attached to the package substrate 120 and the lid portion 226L of the lid assembly 226. In some embodiments (not specifically illustrated), the stiffeners 229 may be attached to the package substrate 120 and the lid assembly 226 using adhesives similar to the adhesive 228 used to attach the lid assembly 226 to the package substrate 120.

Each of the stiffeners 229 may have a height H_{S} extending from the lid portion 226L of the lid assembly 226 to the package substrate 120. In addition, the stiffeners 229 may have a width W_{S} and a length L_{S}. In a top-down view (see FIG. 9C), each of the stiffeners 229 may have an L-shape, wherein each leg of the L-shape has a same or different length L_{S}. For example, the height H_{S} may be a sum of the thickness of the package component 150 (e.g., about 1 inch), the protrusion height H_{P}, and the thickness T_{B} of the second TIM 80B. As illustrated, the width W_{S} may be less than the height H_{S}. In addition, the width W_{S} may be less than the length L_{S}. Further, the width W_{S} may be less than the cavity width W_{C}.

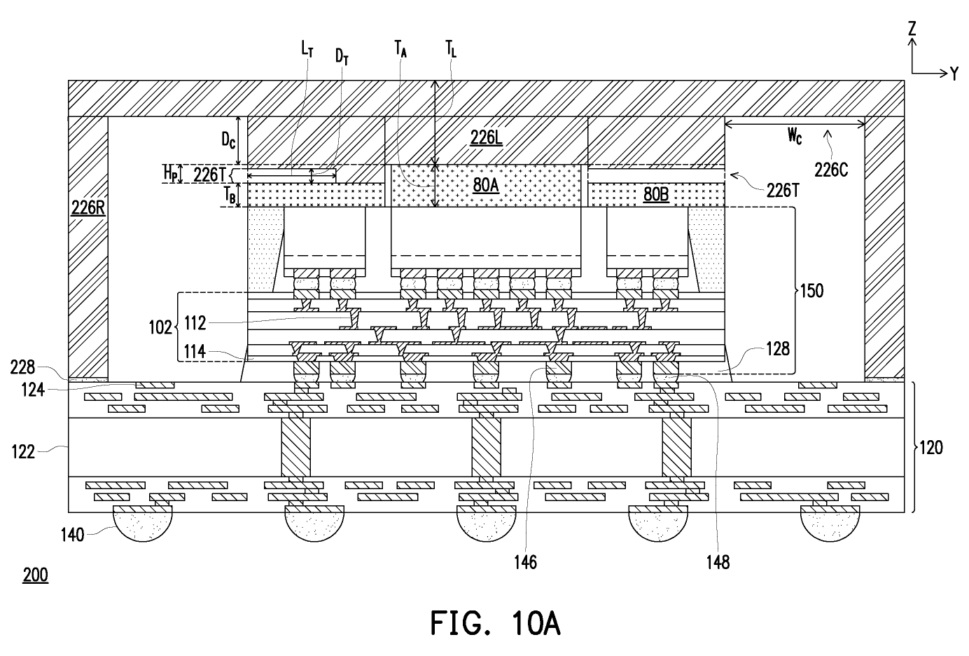

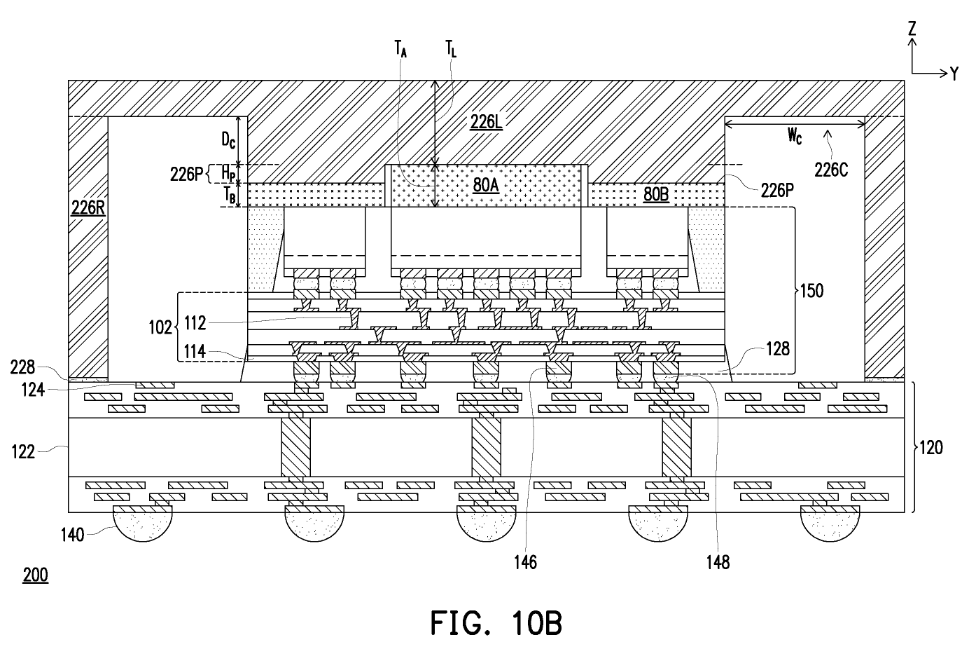

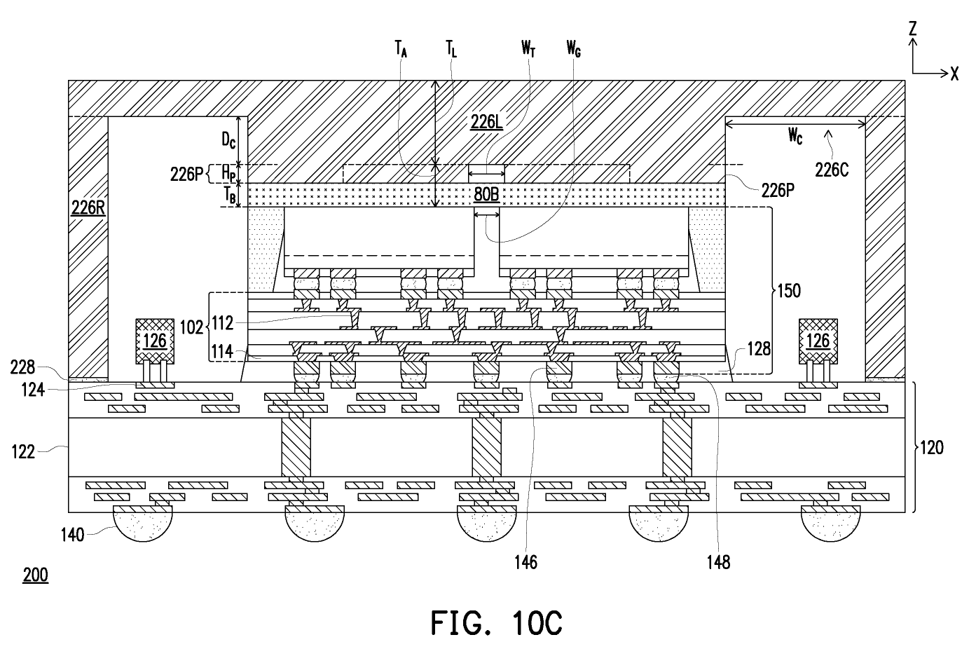

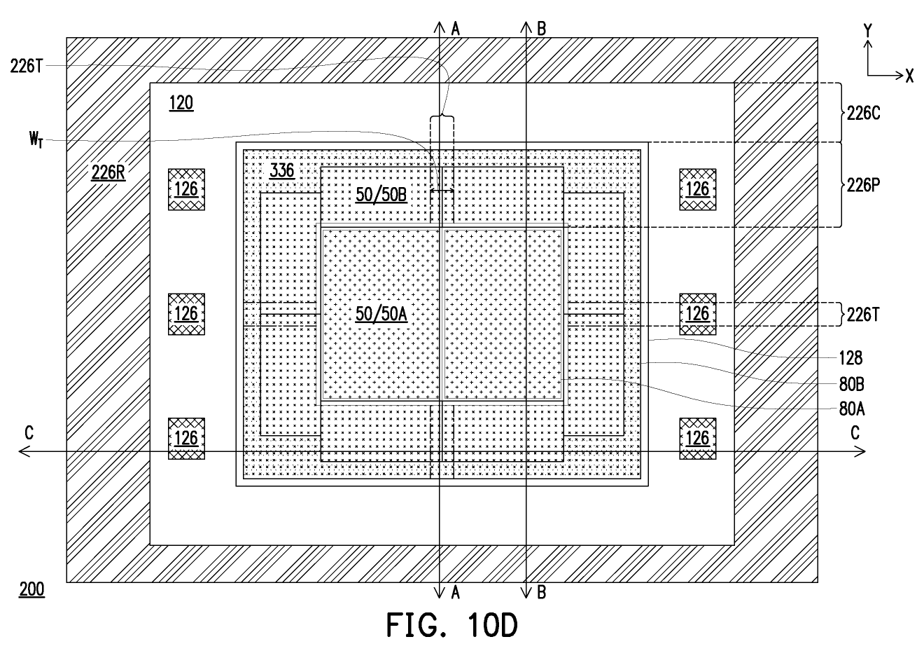

In FIGS. 10A-10D, an integrated circuit package 200 is provided such that the lid assembly 226 further includes trenches 226T extending through the protrusions 226P of the lid portion 226L, in accordance to some embodiments. The integrated circuit package 200 may be formed similarly as described above in connection with any embodiments of the integrated circuit package 100 (see FIGS. 1-9C), unless otherwise specified. FIGS. 10A-10C illustrate side views of the integrated circuit package 200, and FIG. 10D illustrates a plan view (e.g., the X-Y plane) of the integrated circuit package 200, in accordance with some embodiments. In particular, FIG. 10A illustrates the A-A cross-section (e.g., the Y-Z plane) of FIG. 10D, FIG. 10B illustrates the B-B cross-section (e.g., a different cross-section of the Y-Z plane) of FIG. 10D, and FIG. 10C illustrates the C-C cross-section (e.g., the X-Z plane) of FIG. 10D.

The trenches 226T reduce or alleviate stress in the lid portion 226L that may develop, for example, proximal to the perimeter of the TIMs 80. In particular, some stresses tend to be directed or otherwise concentrate in regions of the lid portion 226L proximal to the second TIMs 80B (e.g., along the perimeter of the encapsulant 336). The trenches 226T provide further flexibility in the lid portion 226L while maintaining the heat dissipation advantages. In particular, the contact area and location between the protrusions 226P and the second TIMs 80B are optimized to ensure the above-described advantages are achieved. For example, the trenches 226T are narrow in order to maintain a high proportion of the contact area between the protrusions 226P and the second TIMs 80B. In addition, in accordance some embodiments, the trenches 226T are located directly above gap regions (e.g., comprising the underfill 334 and/or the encapsulant 336) disposed between adjacent ones of the integrated circuit dies 50 along the perimeter (e.g., adjacent ones of the second integrated circuit dies 50B) because those gap regions may contain a lesser amount of heat requiring dissipation as compared to the integrated circuit dies 50, which themselves generate heat during functional use.

In some embodiments, dimensions of the trench 226T may include a trench depth D_{T}, a trench width W_{T}, and a trench length L_{T}. The trench depth D_{T} indicates a depth of the trench 226T through the protrusion 226P. The trench depth D_{T} is less than or equal to the protrusion height H_{P} for the benefit of structural integrity of the lid portion 226L. For example, the trench depth D_{T} may be 10% to 100% of the protrusion height H_{P}. In some embodiments (not specifically illustrated), the trench depth D_{T} may be greater than the protrusion height H_{P}.

The trench width W_{T} may be greater than or equal to a gap width W_{G} of the gap regions between adjacent pairs of the second integrated circuit dies 50B. A larger trench width W_{T} improves flexibility in the lid portion 226L in order to benefit the stress alleviation effects described above. In some embodiments (not specifically illustrated), the trench width W_{T} may be less than the gap width W_{G}.

In some embodiments, the trench length L_{T} may extend entirely through the protrusion 226P. In addition, in some embodiments, the trench length L_{T} may be less than the protrusion 226P, such that the trench 226T begins at the perimeter and extends internally through a partial amount of the protrusion 226P. As such, the trench 226T gives the lid portion 226L flexibility in advantageous locations while further benefiting structural integrity and heat dissipation effects. Referring to FIG. 10A, note that the trench 226T on the left side of the figure demonstrates this embodiment of a partial trench length L_{T}, while the trench 226T on the right side of the figure demonstrates an embodiment in which the trench 226T extends entirely through the protrusion 226P. For example, the trench length L_{T} may extend 10% to 100% through the protrusion 226P. In accordance with some embodiments, the trenches 226T of a particular lid portion 226L may be partial, complete, or combinations thereof. In addition, the trenches 226T may include variations of the other dimensions and features described above (e.g., the trench depth D_{T} and the trench width W_{T}).

Although not specifically illustrated, in some embodiments, the trenches 226T may be formed with rounded corners to benefit stress reduction effects and structural integrity of the lid portion 226L. For example, the rounded corners of the trenches 226T may have radii ranging from 0.025 mm and 0.6 mm.

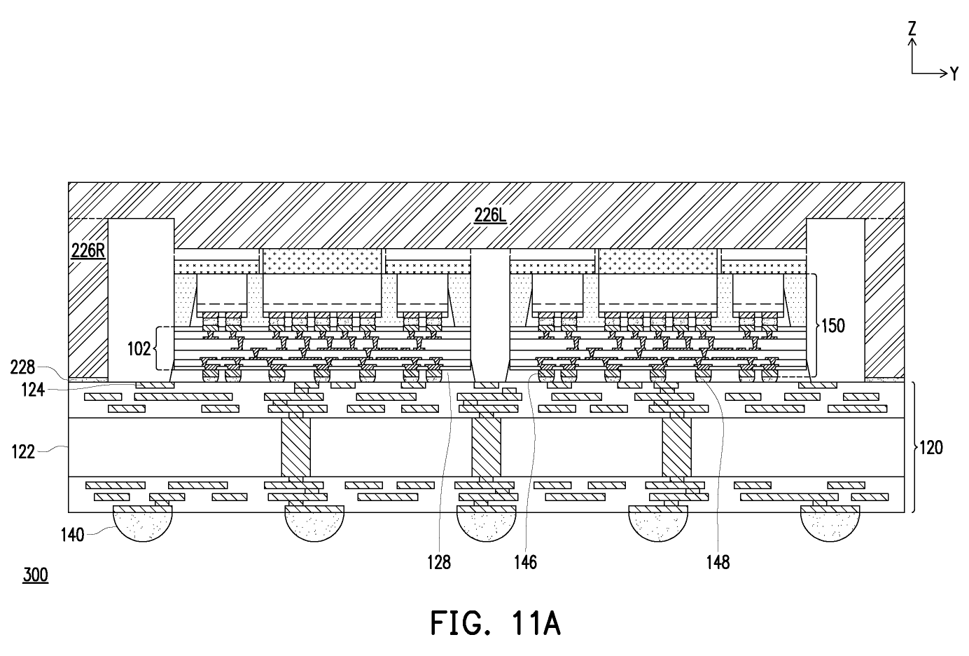

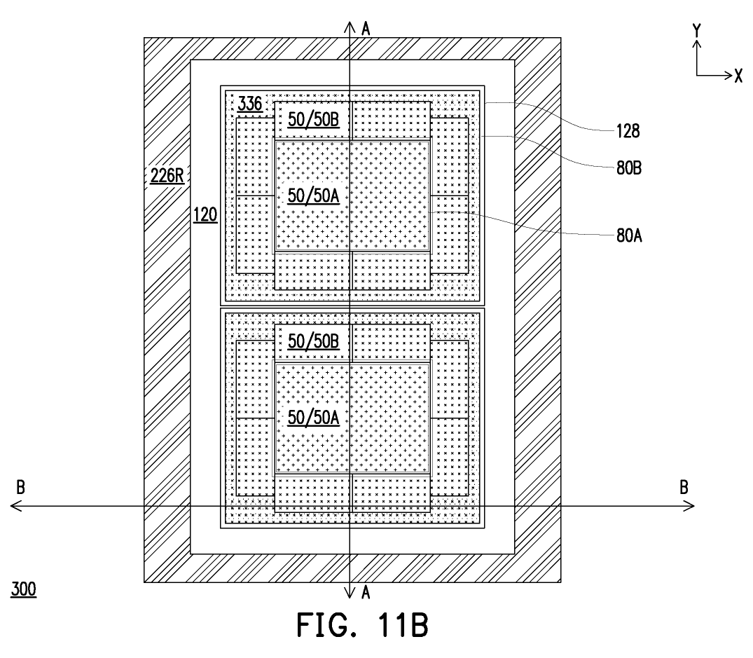

In FIGS. 11A-11B, an integrated circuit package 300 is provided such that multiple package components 150 are attached and enclosed within a single lid assembly 226, in accordance to some embodiments. The integrated circuit package 300 may be formed similarly as described above in connection with the integrated circuit packages 100, 200, unless otherwise specified. FIG. 11A illustrates a side view of the integrated circuit package 300, and FIG. 11B illustrates a plan view (e.g., the X-Y plane) of the integrated circuit package 300, in accordance with some embodiments. In particular, FIG. 11A illustrates the A-A cross-section (e.g., the Y-Z plane) of FIG. 11B. Note that previous figures(see, e.g., FIGS. 8B, 9B, and 10C) may be referenced as representatives of the B-B cross-section (e.g., the X-Z plane) of FIG. 11B.

The integrated circuit package 300 may include some or all of the features described above in connection with the integrated circuit packages 100, 200, such as including a lid assembly 226 having the protrusions 226P, the cavities 226C, and/or the trenches 226T. As illustrated, the cavity 226C may be a single cavity 226C extending within a perimeter of the ring portion 226R. In addition, although illustrated with the underfill 128 being discretely below each of the package components 150, in some embodiments, the underfill 128 is continuous below the package components 150 to reinforce the attachment of the package components 150 to the package substrate 120.

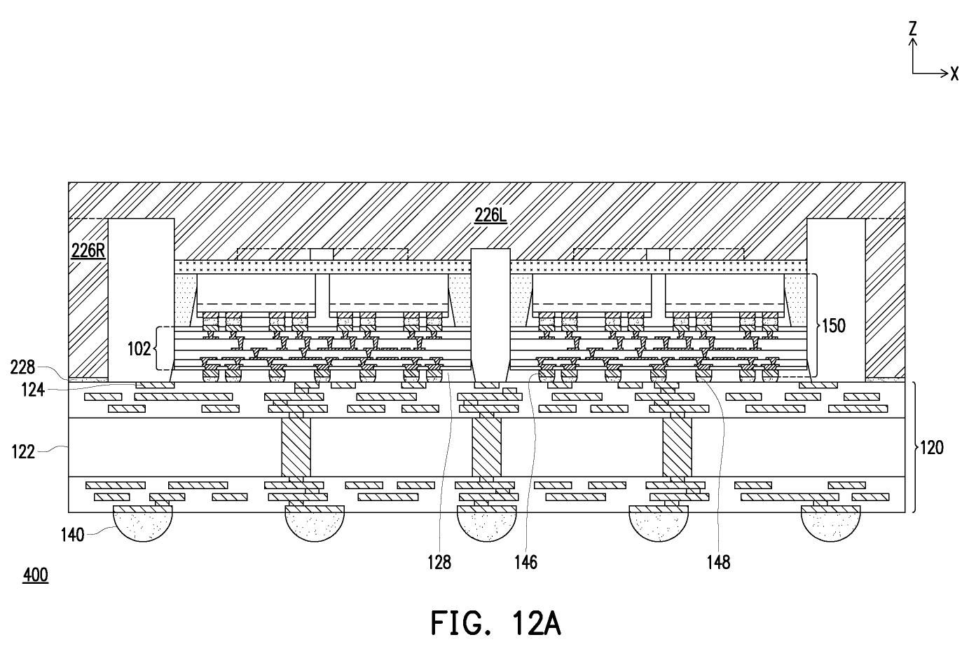

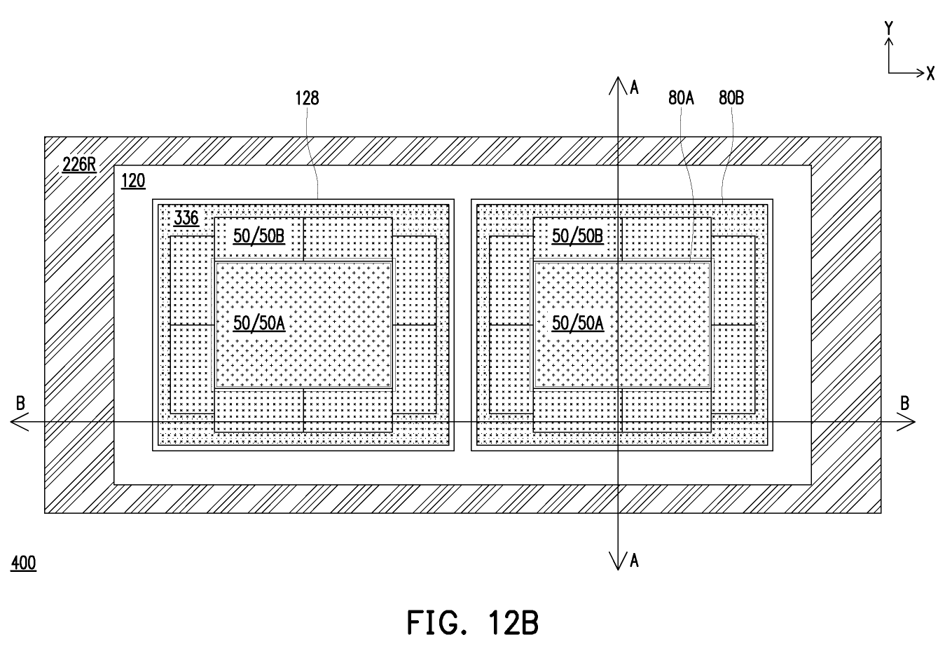

In FIGS. 12A-12B, an integrated circuit package 400 is provided such that multiple package components 150 are attached and enclosed within a single lid assembly 226, in accordance to some embodiments. The integrated circuit package 400 may be formed similarly as described above in connection with the integrated circuit packages 100, 200, 300, unless otherwise specified. FIG. 12A illustrates a side view of the integrated circuit package 400, and FIG. 12B illustrates a plan view (e.g., the X-Y plane) of the integrated circuit package 400, in accordance with some embodiments. In particular, FIG. 12A illustrates the B-B cross-section (e.g., the X-Z plane) of FIG. 12B. Note that previous figures(see, e.g., FIGS. 8A, 9A, and 10A) may be referenced as representatives of the A-A cross-section (e.g., the Y-Z plane) of FIG. 12B.

The integrated circuit package 400 may include some or all of the features described above in connection with the integrated circuit packages 100, 200, 300, such as including a lid assembly 226 having the protrusions 226P, the cavities 226C, and/or the trenches 226T. As illustrated, the cavity 226C may be a single cavity 226C extending within a perimeter of the ring portion 226R. In addition, although illustrated with the underfill 128 being discretely below each of the package components 150, in some embodiments, the underfill 128 is continuous below the package components 150 to reinforce the attachment of the package components 150 to the package substrate 120.

Referring to FIGS. 11A-12B collectively, it should be appreciated that more than two package components 150 may be attached and enclosed within a single lid assembly 226 in a variety of layouts. For example, more than two package components 150 may be arranged in a linear or a matrix layout that features combinations of the embodiments described above. As such, the specifically illustrated or described layouts and combinations are merely examples and are not intended to be limiting.

In FIG. 13, a lid assembly 226 pertaining to any of the above-described integrated circuit packages 100, 200, 300, 400 is illustrated such that an adhesive layer 230 is used to attach the lid portion 226L to the ring portion 226R. For example, the ring portion 226R and the lid portion 226L may be distinct pieces in order to increase the manufacturing variability of the lid assemblies 226. As illustrated, the adhesive layer 230 may have an adhesive height H_{A} that is substantially the same as the cavity depth D_{C}. In some embodiments (not specifically illustrated), the adhesive height H_{A} may be less than the cavity depth D_{C}.

Embodiments may achieve advantages. The thermal interface materials (TIMs) 80 and the lid assembly 226 (e.g., the heat sink structure) improve heat dissipation from the integrated circuit dies 50. In particular, the TIMs 80 are hybrid TIMs, wherein the first TIMs 80A are adapted to dissipating heat from the first integrated circuit dies 50A (e.g., logic devices such as SoC devices) and the second TIMs 80B are adapted to dissipating heat from the second integrated circuit dies 50B (e.g., I/O and/or memory devices). In addition, the lid assembly 226 includes a lid portion 226L having protrusions 226P to make the lid portion 226L conformal to the varying thicknesses of the TIMs 80 in order to maximize contact area. Further, additional features on the lid portion 226L include trenches 226T through the protrusions 226P and cavities 226C near a ring portion 226R improve flexibility of the lid assembly 226. As a result, the above-described embodiments reduce stresses and allow the lid assembly 226 to maintain full contact with the TIMs 80 even when warpage may occur in the package substrate 120 and/or the ring portion 226R.

In an embodiment, a method includes attaching a package component to a package substrate, the package component includes: an interposer disposed over the package substrate; a first die disposed along the interposer; and a second die disposed along the interposer, the second die being laterally adjacent the first die; attaching a first thermal interface material to the first die, the first thermal interface material being composed of a first material; attaching a second thermal interface material to the second die, the second thermal interface material being composed of a second material different from the first material; and attaching a lid assembly to the package substrate, the lid assembly being further attached to the first thermal interface material and the second thermal interface material. In another embodiment, the first thermal interface material has a first thickness measured from the first die, wherein the second thermal interface material has a second thickness measured from the second die, and wherein the first thickness is greater than the second thickness. In another embodiment, a sum of the first thickness and a thickness of the first die is greater than a sum of the second thickness and a thickness of the second die. In another embodiment, the lid assembly includes: a ring portion; and a lid portion, wherein the lid portion comprises a protrusion directly over the second thermal interface material. In another embodiment, the lid portion further comprises a cavity adjacent the ring portion. In another embodiment, the protrusion comprises a trench along an interface with the second die, and wherein a height of the protrusion is greater than a depth of the trench. In another embodiment, attaching the lid assembly to the package substrate includes: attaching the ring portion to the package substrate using a first adhesive layer; and attaching the lid portion to the ring portion using a second adhesive layer.

In an embodiment, a semiconductor package includes: an interposer being attached to a package substrate; a first die and a second die being attached to the interposer; an encapsulant encapsulating lateral sides of the first die and the second die, a first surface of the first die, a second surface of the second die, and a third surface of the encapsulant being level; a first thermal interface material being attached to the first surface, the first thermal interface material having a first thermal conductivity; a second thermal interface material being attached to the second surface, the second thermal interface material having a second thermal conductivity, the second thermal conductivity being different from the first thermal conductivity; and a lid assembly being attached to the package substrate, the first thermal interface material, and the second thermal interface material. In another embodiment, in a plan view a surface area of the first thermal interface material is less than a surface area of the first surface, and wherein in the plan view a surface area of the second thermal interface material is greater than a surface area of the second surface. In another embodiment, the first thermal conductivity is greater than the second thermal conductivity. In another embodiment, the semiconductor package further includes a third die attached to the interposer, and wherein the second thermal interface material is attached to a fourth surface of the third die. In another embodiment, in a plan view a surface area of the second thermal interface material is greater than a total surface area of the second surface and the fourth surface. In another embodiment, the lid assembly includes: a flat portion, the flat portion being attached to the first thermal interface material; and a protrusion extending from the flat portion, the protrusion being attached to the second thermal interface material. In another embodiment, the second die and the third die are separated by a gap along sidewalls of the second die and the third die, wherein the protrusion comprises a trench, and wherein in a plan view the trench extends directly over the gap. In another embodiment, the semiconductor package further includes a stiffener connecting a lid portion of the lid assembly to the package substrate, wherein the stiffener is interposed between a ring portion of the lid assembly and the second die.

In an embodiment, a semiconductor package includes: a semiconductor component, comprising: a package substrate; a first die disposed over the package substrate, the first die being a system-on-a-chip die; and a second die and a third die disposed over the package substrate; and a heat sink structure attached to the semiconductor component, the heat sink structure comprising: a ring portion, the ring portion being attached to a surface of the package substrate; a first thermal interface material, the first thermal interface material being attached to a surface of the first die; a second thermal interface material, the second thermal interface material being attached to a surface of the second die and a surface of the third die; and a lid portion, the lid portion being attached to the first thermal interface material, the second thermal interface material, and the ring portion. In another embodiment, the first thermal interface material has a greater thermal conductivity than the second thermal interface material. In another embodiment, the lid portion has a greater thermal conductivity than the first thermal interface material. In another embodiment, the lid portion includes: a first surface adjacent the first thermal interface material; and a second surface adjacent the second thermal interface material, wherein the first surface and the second surface are on different planes. In another embodiment, the lid portion comprises a cavity extending in a first loop, wherein the ring portion extends in a second loop, and wherein the first loop is concentric with the second loop.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
an interposer being attached to a package substrate;
a first die and a second die being attached to the interposer;
an encapsulant encapsulating lateral sides of the first die and the second die, a first surface of the first die, a second surface of the second die, and a third surface of the encapsulant being level;
a first thermal interface material being attached to the first surface, the first thermal interface material having a first thermal conductivity;
a second thermal interface material being attached to the second surface and the third surface, the second thermal interface material having a second thermal conductivity, the second thermal conductivity being different from the first thermal conductivity; and
a lid assembly being attached to the package substrate, the first thermal interface material, and the second thermal interface material.

2. The semiconductor package of claim 1, wherein in a plan view a surface area of the first thermal interface material is less than a surface area of the first surface, and wherein in the plan view a surface area of the second thermal interface material is greater than a surface area of the second surface.

3. The semiconductor package of claim 1, wherein the first thermal conductivity is greater than the second thermal conductivity.

4. The semiconductor package of claim 1, further comprising a third die attached to the interposer, and wherein the second thermal interface material is attached to a fourth surface of the third die.

5. The semiconductor package of claim 4, wherein in a plan view a surface area of the second thermal interface material is greater than a total surface area of the second surface and the fourth surface.

6. The semiconductor package of claim 4, wherein the lid assembly comprises:
a flat portion, the flat portion being attached to the first thermal interface material; and
a protrusion extending from the flat portion, the protrusion being attached to the second thermal interface material.

7. The semiconductor package of claim 6, wherein the second die and the third die are separated by a gap along sidewalls of the second die and the third die, wherein the protrusion comprises a first trench, and wherein the first trench overlaps the gap in a first cross-sectional view.

8. The semiconductor package of claim 7, wherein the first trench further overlaps the second die in the first cross-sectional view.

9. The semiconductor package of claim 1, further comprising a stiffener connecting a lid portion of the lid assembly to the package substrate, wherein the stiffener is interposed between a ring portion of the lid assembly and the second die.

10. A semiconductor package, comprising:
a semiconductor component, comprising:
a package substrate;
a first die disposed over the package substrate, the first die being a system-on-a-chip die; and
a second die and a third die disposed over the package substrate; and
a heat sink structure attached to the semiconductor component, the heat sink structure comprising:
a ring portion, the ring portion being attached to a surface of the package substrate;
a first thermal interface material, the first thermal interface material interfacing a surface of the first die;
a second thermal interface material, the second thermal interface material interfacing a surface of the second die and a surface of the third die, wherein the first thermal interface material has a different thermal conductivity than the second thermal interface material; and
a lid portion, the lid portion being attached to the first thermal interface material, the second thermal interface material, and the ring portion.

11. The semiconductor package of claim 10, wherein the first thermal interface material has a greater thermal conductivity than the second thermal interface material.

12. The semiconductor package of claim 11, wherein the lid portion has a greater thermal conductivity than the first thermal interface material.

13. The semiconductor package of claim 10, wherein the lid portion comprises:
a first surface adjacent the first thermal interface material; and
a second surface adjacent the second thermal interface material, wherein the first surface and the second surface are on different planes.

14. The semiconductor package of claim 10, wherein the lid portion comprises a cavity extending in a first loop, wherein the ring portion extends in a second loop, and wherein the first loop is concentric with the second loop.

15. A semiconductor package, comprising:
a first die, a second die, and a third die bonded to an interposer, wherein the first die is between the second die and the third die;
an encapsulant encapsulating the first die, the second die, and the third die;
a first thermal interface material interfacing a top surface of the first die, the first thermal interface material having a first thermal conductivity; and
a second thermal interface material interfacing the second die and the third die, the second thermal interface material having a second thermal conductivity that is less than the first thermal conductivity, wherein the second thermal interface material surrounds the first thermal interface material in a plan view.

16. The semiconductor package of claim 15, wherein the second thermal interface material further interfaces a top surface of the encapsulant.

17. The semiconductor package of claim 15, wherein a height of the first thermal interface material is greater than a height of the second thermal interface material in a cross-sectional view.

18. The semiconductor package of claim 15, further comprising:
a package substrate bonded to an opposing side of the interposer as the first die, the second die, and the third die; and
a lid assembly attached to the package substrate, the first thermal interface material, and the second thermal interface material.

19. The semiconductor package of claim 18, wherein the lid assembly comprises:
a flat portion interfacing the first thermal interface material; and
a protruding portion interfacing the second thermal interface material.

20. The semiconductor package of claim 19, wherein the lid assembly further comprises:
a trench in the protruding portion, wherein the trench overlaps the second die in a cross-sectional view.
